(19) United States
(12) Patent Application Publication
(10) Pub. No.: US 2021/0333718 A1
(43) Pub. Date: Oct. 28, 2021

(54) EXTREME ULTRAVIOLET LIGHT GENERATION SYSTEM AND ELECTRONIC DEVICE MANUFACTURING METHOD

(71) Applicant: Gigaphoton Inc., Tochigi (JP)

(72) Inventors: Yuichi NISHIMURA, Oyama-shi (JP); Takayuki YABU, Oyama-shi (JP); Tsukasa HORI, Oyama-shi (JP)

(73) Assignee: Gigaphoton Inc., Tochigi (JP)

(21) Appl. No.: 17/366,219

(22) Filed: Jul. 2, 2021

Related U.S. Application Data
(63) Continuation of application No. PCT/JP2019/006345, filed on Feb. 20, 2019.

(51) Int. Cl. G03F 7/20; H05G 2/00

(52) U.S. Cl. CPC G03F 7/7055; G03F 7/70033; H05G 2/008; G03F 7/70041; G03F 7/70025

(57) ABSTRACT

An extreme ultraviolet light generation system according to an aspect of the present disclosure includes a first actuator that changes a travel direction of prepulse laser light to be output from a first optical element arranged on an optical path of the prepulse laser light between a prepulse laser device and a beam combiner, and a second actuator that changes irradiation positions of the prepulse laser light and main pulse laser light to be output from a light concentrating optical system, a plurality of sensors that detect light radiated from a predetermined region by a target being irradiated with the main pulse laser light, and a controller. Here, the controller controls the first actuator so that an evaluation value calculated from output of the plurality of sensors approaches a target value, and thereafter, controls the second actuator so that the evaluation value approaches the target value.

### CROSS-REFERENCE TO RELATED APPLICATIONS

The present application claims the benefit of International Application No. PCT/JP2019/006345, filed on Feb. 20, 2019, the entire contents of which are hereby incorporated by reference.

### BACKGROUND

### 1. Technical Field

The present disclosure relates to an extreme ultraviolet light generation system and an electronic device manufacturing method.

### 2. Related Art

Recently, miniaturization of a transfer pattern in optical lithography of a semiconductor process has been rapidly proceeding along with miniaturization of the semiconductor process. In the next generation, microfabrication at 20 nm or less will be required. Therefore, it is expected to develop an exposure apparatus that combines an apparatus for generating extreme ultraviolet (EUV) light having a wavelength of about 13 nm with a reduced projection reflection optical system.

As an EUV light generation apparatus, three types of apparatuses have been proposed: a laser produced plasma (LPP) type apparatus using plasma generated by irradiating a target substance with laser light, a discharge produced plasma (DPP) type apparatus using plasma generated by discharge, and a synchrotron radiation (SR) type apparatus using synchrotron radiation light.

### LIST OF DOCUMENTS

### Patent Documents

Patent Document 1: International Publication No. WO2018/131146

Patent Document 2: U.S. Pat. No. 8,569,722

### SUMMARY

An extreme ultraviolet light generation system according to an aspect of the present disclosure includes a chamber; a target supply unit configured to supply a target to a predetermined region in the chamber; a prepulse laser device configured to emit prepulse laser light to be radiated to the target; a main pulse laser device configured to emit main pulse laser light to be radiated to the target irradiated with the prepulse laser light; a beam combiner configured to substantially match an optical path of the prepulse laser light and an optical path of the main pulse laser light; a light concentrating optical system arranged on an optical path of the prepulse laser light and the main pulse laser light output from the beam combiner and configured to concentrate the prepulse laser light and the main pulse laser light on the vicinity of the predetermined region; a first optical element arranged on the optical path of the prepulse laser light between the prepulse laser device and the beam combiner; a first actuator configured to change a travel direction of the prepulse laser light to be output from the first optical element; a second actuator configured to change irradiation positions of the prepulse laser light and the main pulse laser light in a plane orthogonal to the travel direction of the prepulse laser light and the main pulse laser light output from the light concentrating optical system; a plurality of sensors configured to detect light radiated from the predetermined region by the target being irradiated with the main pulse laser light; and a controller configured to control the first actuator and the second actuator based on output of the plurality of sensors, as performing, within one burst period, first control to control the first actuator so that an evaluation value calculated from the output of the plurality of sensors approaches a target value, and after the first control, second control to control the second actuator so that the evaluation value approaches the target value.

An electronic device manufacturing method according to an aspect of the present disclosure includes generating extreme ultraviolet light as turning a target into plasma by irradiating the target with prepulse laser light and main pulse laser light using an extreme ultraviolet light generation system, emitting the extreme ultraviolet light to an exposure apparatus, and exposing a photosensitive substrate to the extreme ultraviolet light in the exposure apparatus to manufacture an electronic device. Here, the extreme ultraviolet light generation system includes a chamber; a target supply unit configured to supply the target to a predetermined region in the chamber; a prepulse laser device configured to emit the prepulse laser light to be radiated to the target; a main pulse laser device configured to emit the main pulse laser light to be radiated to the target irradiated with the prepulse laser light; a beam combiner configured to substantially match an optical path of the prepulse laser light and an optical path of the main pulse laser light; a light concentrating optical system arranged on an optical path of the prepulse laser light and the main pulse laser light output from the beam combiner and configured to concentrate the prepulse laser light and the main pulse laser light on the vicinity of the predetermined region; a first optical element arranged on the optical path of the prepulse laser light between the prepulse laser device and the beam combiner; a first actuator configured to change a travel direction of the prepulse laser light to be output from the first optical element; a second actuator configured to change irradiation positions of the prepulse laser light and the main pulse laser light in a plane orthogonal to a travel direction of the prepulse laser light and the main pulse laser light output from the light concentrating optical system; a plurality of sensors configured to detect light radiated from the predetermined region by the target being irradiated with the main pulse laser light; and a controller configured to control the first actuator and the second actuator based on output of the plurality of sensors, as performing, within one burst period, first control to control the first actuator so that an evaluation value calculated from the output of the plurality of sensors approaches a target value, and after the first control, second control to control the second actuator so that the evaluation value approaches the target value.

### BRIEF DESCRIPTION OF THE DRAWINGS

Embodiments of the present disclosure will be described below merely as examples with reference to the accompanying drawings.

FIG. 1 is a diagram schematically showing an exemplary configuration of an LPP EUV light generation system.

FIG. 2 is a view showing an arrangement example of EUV light sensors.

FIG. 3 is a side view of FIG. 2.

FIG. 4 is a graph exemplarily showing a change in EUV energy and a change in an EUV centroid position in each burst period when EUV centroid control is not performed.

FIG. 5 is a graph exemplarily showing the change in the EUV energy and the change in the EUV centroid position in each burst period when the EUV centroid control is performed.

FIG. 6 is a diagram schematically showing the configuration of the EUV light generation system according to a first embodiment.

FIG. 7 is a diagram schematically showing the relationship between the EUV centroid position and a relative positional deviation amount of prepulse laser light and CO2 laser light.

FIG. 8 is a diagram schematically showing the relationship between the EUV centroid position and the relative positional deviation amount of the prepulse laser light and the CO2 laser light.

FIG. 9 is a graph showing operation of the EUV light generation system according to the first embodiment.

FIG. 10 is a diagram schematically showing a state of timing before a first burst irradiation indicated by (i) in FIG. 9.

FIG. 11 is a diagram schematically showing a state of timing at a burst beginning part indicated by (ii) in FIG. 9.

FIG. 12 is a diagram schematically showing a state of timing in a steady state of droplet shift indicated by (iii) in FIG. 9.

FIG. 13 is a diagram schematically showing a state of timing at the second half of the burst indicated by (iv) in FIG. 9.

FIG. 14 is a diagram schematically showing a state of timing at the second half of the burst indicated by (v) in FIG. 9.

FIG. 15 is a diagram schematically showing a state of timing at a burst pause period indicated by (vi) in FIG. 9.

FIG. 16 is a diagram schematically showing a state of timing in a steady state of droplet shift at the burst beginning part indicated by (vii) in FIG. 9.

FIG. 17 is a diagram schematically showing a state of timing at the second half of the burst indicated by (viii) in FIG. 9.

FIG. 18 is a diagram schematically showing a state of timing at the burst pause period indicated by (ix) in FIG. 9.

FIG. 19 is a diagram schematically showing a state of timing in the steady state of the droplet shift at the burst beginning part indicated by (x) in FIG. 9.

FIG. 20 is a diagram schematically showing a state of timing at the second half of the burst indicated by (xi) in FIG. 9.

FIG. 21 is a flowchart showing an example of a control operation in the first embodiment.

FIG. 22 schematically illustrates the configuration of the EUV light generation system according to a second embodiment.

FIG. 23 is a diagram schematically showing the relationship between the EUV centroid position and a relative positional deviation amount ΔPPL1 of first prepulse laser light with respect to irradiation positions of second prepulse laser light and the CO2 laser light.

FIG. 24 is a diagram schematically showing the configuration of the EUV light generation system according to a third embodiment.

FIG. 25 is a diagram schematically showing the configuration of the EUV light generation system according to a fourth embodiment.

FIG. 26 is a diagram schematically showing the relationship between the EUV centroid position and a relative positional deviation amount ΔPPL1_2 of irradiation positions of the prepulse laser light and the CO2 laser light.

FIG. 27 is a diagram showing a schematic configuration of an exposure apparatus connected to the EUV light generation system.

### DESCRIPTION OF EMBODIMENTS

### Contents

1. Description of terms
2. Overall description of extreme ultraviolet light generation system

2.1 Configuration

2.2 Operation

2.3 Arrangement example of EUV light sensor

2.4 Overview of EUV centroid control

### 3. Problem

### 4. First Embodiment

4.1 Overview

4.2 Configuration

4.3 Equation for EUV centroid value

4.4 Relationship between relative positional deviation amount ΔPPL of prepulse laser light and EUV centroid position

4.5 Operation

4.6 Target value of EUV centroid value

4.7 Effect

### 5. Second Embodiment

5.1 Configuration

5.2 Equation for EUV centroid value

5.3 Operation

5.4 Effect

5.5 Others

### 6. Third Embodiment

6.1 Configuration

6.2 Operation

6.3 Effect

### 7. Fourth Embodiment

7.1 Configuration

7.2 Equation for EUV centroid value

7.3 Operation

7.4 Effect

8. Example of electronic device manufacturing method using EUV light generation system

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numerals, and duplicate description thereof is omitted.

### 1. Description of Terms

A “target” is an object to be irradiated with laser light introduced into a chamber. The target irradiated with laser light is turned into plasma and emits EUV light. A “droplet” formed of liquid target substance is a form of a target. The target serves as a plasma generation source.

A “target trajectory” is a path along which a target output into the chamber travels. The target trajectory intersects, in a plasma generation region, with an optical path of the laser light introduced into the chamber.

A “plasma generation region” is a region in which a target output into the chamber is irradiated with laser light and in which the target is turned into plasma. The plasma generation region corresponds to a region where generation of plasma for outputting EUV light is started.

“Plasma light” is radiation light radiated from plasma. Radiation light radiated from a target turned into plasma is a form of plasma light, and EUV light is contained in the radiation light.

The expression “EUV light” is an abbreviation for “extreme ultraviolet light.” An “extreme ultraviolet light generation system” is referred to as an “EUV light generation system.”

A “burst operation” by the extreme ultraviolet light generation system is an operation that repeats a burst period in which EUV light is output at a predetermined repetition frequency for a specific period and a pause period in which EUV light is not output for a specific period. During the burst period, pulse laser light is output from a laser device and radiated to the target. During the pause period, the output of the pulse laser light is stopped or propagation of the pulse laser light to the plasma generation region is suppressed.

### 2. Overall Description of Extreme Ultraviolet Light Generation System

### 2.1 Configuration

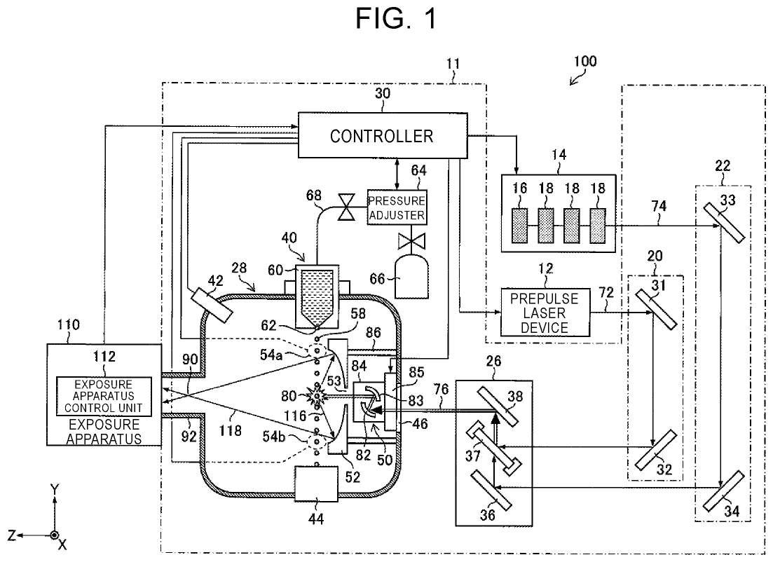

FIG. 1 schematically shows an exemplary configuration of an LPP EUV light generation system 100. An EUV light generation apparatus 11 is used with at least one laser device. The EUV light generation apparatus 11 shown in FIG. 1 is used with a prepulse laser device 12 and a main pulse laser device 14 as the laser device. In the present disclosure, a system including the EUV light generation apparatus 11, the prepulse laser device 12, and the main pulse laser device 14 is referred to as the EUV light generation system 100.

Either or both of the prepulse laser device 12 and the main pulse laser device 14 may be a master oscillator power amplifier (MOPA) system. The MOPA system includes a laser oscillator and at least one laser amplifier. As the prepulse laser device 12, for example, a YAG laser device that emits pulse laser light having a wavelength of 1.06 μm may be used. “YAG” is an abbreviation for yttrium aluminum garnet. The YAG laser device uses a YAG crystal as a laser medium for an oscillator and/or an amplifier. The YAG crystal may be doped with an element such as neodymium (Nd).

The main pulse laser device 14 is, for example, a CO2 laser device. “CO2” stands for carbon dioxide. The CO2 laser device uses a CO2 gas as a laser medium for an oscillator and/or an amplifier. The main pulse laser device 14 shown in FIG. 1 includes a master oscillator 16, an optical isolator (not shown), and a CO2 laser amplifier 18.

The master oscillator 16 emits laser light having a wavelength in an amplification region of the CO2 laser amplifier 18 at a predetermined repetition frequency. A solid-state laser device may be adopted as the master oscillator 16. The wavelength of the laser light emitted from the master oscillator 16 may be, for example, 10.59 μm and the repetition frequency of pulse oscillation may be, for example, 100 kHz.

The CO2 laser amplifier 18 is arranged on the optical path of the laser light emitted from the master oscillator 16. Although three CO2 laser amplifiers 18 are shown in FIG. 1, the main pulse laser device 14 may include n CO2 laser amplifiers 18. Here, n may be an integer of 1 or more.

The EUV light generation apparatus 11 includes a first laser light transmission device 20, a second laser light transmission device 22, a beam combiner 26, a chamber 28, and a controller 30.

Each of the first laser light transmission device 20 and the second laser light transmission device 22 includes an optical element for defining a transmission state of laser light, and an actuator for adjusting the position, posture, and the like of the optical element.

The first laser light transmission device 20 includes a first high reflection mirror 31 and a second high reflection mirror 32 as an optical element for defining the travel direction of the laser light emitted from the prepulse laser device 12. The laser light emitted from the prepulse laser device 12 is referred to as prepulse laser light 72. The first laser light transmission device 20 may form a laser optical path for guiding the prepulse laser light 72 to the beam combiner 26.

The second laser light transmission device 22 includes a third high reflection mirror 33 and a fourth high reflection mirror 34 as an optical element for defining the travel direction of the laser light emitted from the main pulse laser device 14. The laser light emitted from the main pulse laser device 14 is referred to as main pulse laser light 74. The second laser light transmission device 22 may form a laser light path for guiding the main pulse laser light 74 to the beam combiner 26.

The beam combiner 26 includes a fifth high reflection mirror 36, a dichroic mirror 37, and a sixth high reflection mirror 38. The fifth high reflection mirror 36 reflects the main pulse laser light 74 transmitted through the second laser light transmission device 22 toward the dichroic mirror 37.

The dichroic mirror 37 is an optical element that reflects the prepulse laser light 72 and transmits the main pulse laser light 74. The dichroic mirror 37 may be a diamond substrate coated with a film that reflects the prepulse laser light 72 at high reflectance and transmits the main pulse laser light 74 at high transmittance. The dichroic mirror 37 transmits the main pulse laser light 74 reflected by the fifth high reflection mirror 36 and reflects the prepulse laser light 72 transmitted through the first laser light transmission device 20, thereby substantially matches the optical paths of the two lights. Here, “substantially match” is not limited to a case of strictly matching, but means “approximately match” including a predetermined allowable range that can be regarded as substantially matching. Substantially matching the optical paths of a plurality of lights is referred to as multiplexing.

The sixth high reflection mirror 38 reflects pulse laser light 76 multiplexed by the dichroic mirror 37 to define the travel direction of the pulse laser light 76. The pulse laser light 76 is either or both of the prepulse laser light 72 and the main pulse laser light 74. The beam combiner 26 may be fixed to the chamber 28.

The chamber 28 is a sealable container. The chamber 28 may be formed in a hollow spherical shape or a cylindrical shape, for example. The chamber 28 includes a droplet generator 40, a droplet detection sensor 42, and a droplet collector 44. A window 46 for introducing pulse laser light 76 into the chamber 28 is arranged on a wall of the chamber 28. The pulse laser light 76 output from the beam combiner 26 passes through the window 46.

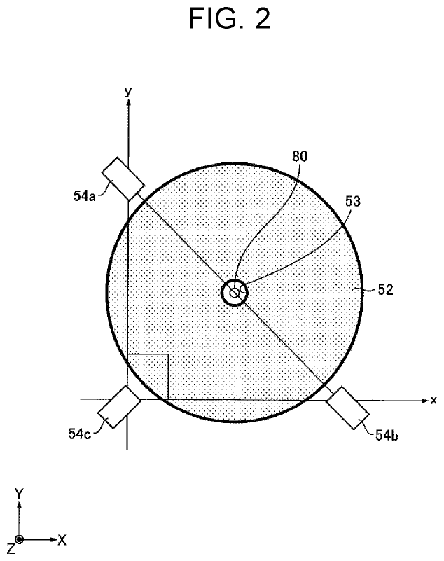

A laser light concentrating unit 50 and an EUV light concentrating mirror 52 are located in the chamber 28. Further, a plurality of EUV light sensors including EUV light sensors 54a, 54b are arranged on the wall of the chamber 28. Although the EUV light sensors 54a, 54b are shown in FIG. 1 for convenience of illustration, three EUV light sensors 54a, 54b, 54c are arranged on the wall of the chamber 28 as shown in FIG. 2.

The droplet generator 40 is configured to supply a droplet 58 of the target substance into the chamber 28, and for example, is arranged to penetrate through the wall of the chamber 28. The material of the target substance may include, but not limited to, tin, terbium, gadolinium, lithium, xenon, or a combination of any two or more thereof.

The droplet generator 40 includes a tank 60 for storing the target substance, a nozzle 62 including a nozzle hole for outputting the target substance, and a piezoelectric element (not shown) arranged at the nozzle 62. The tank 60 may be formed in a hollow cylindrical shape. The target substance is stored in the hollow tank 60. At least the inside of the tank 60 is made of a material that is less likely to react with the target substance. For example, SiC, SiO₂, Al₂O₃, molybdenum, tungsten, tantalum, or the like can be used as the material that is less likely to react with tin, which is an example of the target substance. Further, a heater (not shown) and a temperature sensor (not shown) are fixed to the outer side surface of the tank 60.

The EUV light generation apparatus 11 includes a pressure adjuster 64 which adjusts the pressure in the tank 60. The pressure adjuster 64 is arranged at a pipe 68 between an inert gas supply unit 66 and the tank 60. The inert gas supply unit 66 may include a gas cylinder filled with inert gas such as helium or argon. The inert gas supply unit 66 can supply the inert gas into the tank 60 through the pressure adjuster 64.

The pressure adjuster 64 may be connected to an exhaust pump (not shown). The pressure adjuster 64 can operate the exhaust pump to exhaust the gas in the tank 60. The pressure adjuster 64 may include a solenoid valve (not shown) for supplying and exhausting of gas, a pressure sensor (not shown), and the like. The pressure adjuster 64 can detect the pressure in the tank 60 using the pressure sensor. The pressure adjuster 64 is connected to the controller 30.

The nozzle 62 is arranged at the bottom surface of the cylindrical tank 60. The plasma generation region 80 in the chamber 28 is located on the extension line of the center axis direction of the nozzle 62. For convenience of description in FIG. 1, a three-dimensional XYZ orthogonal coordinate system is introduced and the center axis direction of the nozzle 62 is defined as the Y-axis direction. The direction in which the EUV light is output from the chamber 28 toward the exposure apparatus 110 is defined as the Z-axis direction, and the direction perpendicular to the paper surface in FIG. 1 is defined as the X-axis direction.

The nozzle hole of the nozzle 62 is formed in a shape such that the molten target substance is ejected into the chamber 28 in a jet form. Liquid tin may be employed as an example of the target substance to be output through the nozzle hole.

The droplet generator 40 forms the droplet 58 with, for example, a continuous jet method. In the continuous jet method, the nozzle 62 is vibrated to give standing waves to the flow of the target ejected in a jet form, thereby periodically separating the target substance. The separated target substance may form a free interface by its surface tension to form the droplet 58.

A piezoelectric element (not shown) is arranged at the nozzle 62. The piezoelectric element can be an element constituting a droplet forming mechanism that applies vibration to the nozzle 62 necessary for forming the droplet 58. The piezoelectric element is connected to a piezoelectric power source (not shown). The piezoelectric power source supplies power to the piezoelectric element. The piezoelectric power source is connected to the controller 30 and the controller 30 controls power supply to the piezoelectric element.

The droplet detection sensor 42 detects any or more of the presence, trajectory, position, and velocity of the droplet 58 output into the chamber 28. The droplet detection sensor 42 may be configured by any of a photodiode, a photodiode array, an avalanche photodiode, a photomultiplier tube, a multi-pixel photon counter, an image sensor such as a charge-coupled device (CCD) camera, and an image intensifier.

As the droplet detection sensor 42, for example, it is possible to employ a configuration including a light source unit and a light receiving unit. The light source unit and the light receiving unit may be arranged at positions facing each other across the trajectory of the droplet 58. Although only one droplet detection sensor 42 is shown in FIG. 1, a plurality of the droplet detection sensors 42 may be arranged in the chamber 28.

The laser light concentrating unit 50 includes a light concentrating optical system that concentrates the pulse laser light 76 entering the chamber 28 through the window 46 on the plasma generation region 80. The laser light concentrating unit 50 includes a high reflection off-axis paraboloidal mirror 82, a high reflection concave off-axis elliptical mirror 83, a mirror support plate 84, and a three axis stage 85. The high reflection off-axis paraboloidal mirror 82 is held by a mirror holder (not shown) and is fixed to the mirror support plate 84. The high reflection concave off-axis elliptical mirror 83 is held by a mirror holder (not shown) and is fixed to the mirror support plate 84.

The three axis stage 85 is a stage capable of moving the mirror support plate 84 in mutually orthogonal directions of three axes of the X axis, the Y axis, and the Z axis. The three axis stage 85 includes an actuator (not shown) and is electrically driven in accordance with a command from the controller 30.

The EUV light concentrating mirror 52 is supported by the support member 86. The support member 86 is fixed to the inner wall of the chamber 28. The EUV light concentrating mirror 52 has a spheroidal reflection surface. The EUV light concentrating mirror 52 has a first focal point and a second focal point. A multilayer reflection film in which, for example, molybdenum and silicon are alternately stacked is formed on a reflection surface of the EUV light concentrating mirror 52. The EUV light concentrating mirror 52 is arranged, for example, such that the first focal point is located in the plasma generation region 80 and the second focal point is located at an intermediate focal (IF) point 90. A through hole 53 is formed at the center of the EUV light concentrating mirror 52, and the pulse laser light 76 passes through the through hole 53.

The droplet collector 44 is located on the extension line of the direction in which the droplet 58 output from the droplet generator 40 into the chamber 28 travels. In FIG. 1, the dropping direction of the droplet 58 is parallel to the Y axis, and the droplet collector 44 is located at a position facing the droplet generator 40 in the Y-axis direction.

Further, the chamber 28 is provided with an exhaust device (not shown) and a pressure sensor (not shown), and is connected to a gas supply device (not shown).

The EUV light generation apparatus 11 includes a connection portion 92 providing communication between the internal space of the chamber 28 and the internal space of the exposure apparatus 110. A wall in which an aperture is formed is arranged in the connection portion 92. The aperture is arranged to be located at the second focal point of the EUV light concentrating mirror 52 being the intermediate focal point 90.

The exposure apparatus 110 includes an exposure apparatus control unit 112, and the exposure apparatus control unit 112 is connected to the controller 30.

The controller 30 controls the entire EUV light generation system 100. The controller 30 is connected to each of the prepulse laser device 12, the main pulse laser device 14, the droplet generator 40, the pressure adjuster 64, the droplet detection sensor 42, the EUV light sensors 54a to 54c, and the three axis stage 85. Further, the controller 30 is connected to an exhaust device (not shown), a pressure sensor (not shown), a gas supply control valve (not shown), and the like.

The controller 30 controls the operation of the droplet generator 40. Further, the controller 30 controls the output timing of the laser light of each of the prepulse laser device 12 and the main pulse laser device 14 based on the detection result of the droplet detection sensor 42. The controller 30 generates a trigger signal that specifies the output timing of the laser light of each of the prepulse laser device 12 and the main pulse laser device 14.

The controller 30 controls, for example, the timing at which the droplet 58 is output, the output direction of the droplet 58, the velocity of the droplet 58, and the like based on the detection result of the droplet detection sensor 42. Further, the controller 30 controls, for example, the oscillation timings of the prepulse laser device 12 and the main pulse laser device 14, the travel directions of the prepulse laser light 72 and the main pulse laser light 74, the light concentration position of the pulse laser light 76, and the like. Such various kinds of control described above are merely exemplary, and other control may be added as necessary or some control functions may be omitted.

In the present disclosure, control devices such as the controller 30 and the exposure apparatus control unit 112 can be realized by a combination of hardware and software of one or more computers. The computer may include a central processing unit (CPU) and a memory. Software is synonymous with programs. A programmable controller is included in the concept of the computer. The CPU included in the computer is an example of the processor. Some or all of the processing functions of the controller 30, the exposure apparatus control unit 112, and other control devices may be realized using an integrated circuit such as a field programmable gate array (FPGA) or an application specific integrated circuit (ASIC).

The functions of a plurality of control devices can also be realized by one control device. Further, in the present disclosure, the controller 30, the exposure apparatus control unit 112, and the like may be connected to each other through a communication network such as a local area network or an Internet line. In a distributed computing environment, program units may be stored in both local and remote memory storage devices.

### 2.2 Operation

Operation of an exemplary LPP EUV light generation system 100 will be described with reference to FIG. 1. The controller 30 controls gas exhaust by the exhaust device and gas supply from the gas supply device so that the pressure in the chamber 28 is within a predetermined range based on the detection value of the pressure sensor arranged in the chamber 28. The predetermined range of the pressure in the chamber 28 is, for example, a value between several Pascals [Pa] and several hundred Pascals [Pa].

The controller 30 controls the heater arranged at the tank 60 to heat the target substance in the tank 60 to a predetermined temperature equal to or higher than the melting point. When tin (Sn) having a melting point of 232° C. is used as the target substance, the controller 30 controls the heater so that the tin in the tank 60 has a predetermined temperature in a temperature range of, for example, 250° C. to 300° C. As a result, the tin in the tank 60 melts into liquid.

Further, the controller 30 controls the pressure adjuster 64 so that the pressure in the tank 60 becomes a pressure at which a jet of liquid tin can be output from the nozzle 62 at a predetermined velocity.

Next, the controller 30 transmits a signal to supply voltage having a predetermined waveform to the piezoelectric element so that the droplet 58 is generated. When the voltage having the predetermined waveform is supplied to the piezoelectric element, the piezoelectric element vibrates. Consequently, regular vibration is given to the jet of the liquid tin output from the nozzle hole. Accordingly, the liquid tin in a jet form is divided into droplets 58, and the droplets 58 having substantially the same volume are periodically generated.

Thus, each droplet 58 output from the droplet generator 40 moves along the droplet trajectory from the nozzle hole to the plasma generation region 80.

The droplet detection sensor 42 includes, for example, a light source unit and a light receiving unit (not shown), and illumination light output from the light source unit passes through a predetermined position of a droplet trajectory along which the droplet 58 travels and is received by the light receiving unit.

The intensity of the light received by the light receiving unit decreases in synchronization with the passage of the droplet 58 through the predetermined position. The change in light intensity is detected by the light receiving unit, and the detection result is output from the light receiving unit to the controller 30.

When the droplet 58 is irradiated with the pulse laser light 76, the controller 30 generates a droplet detection signal at the timing when the detection signal obtained from the droplet detection sensor 42 falls below threshold voltage. The controller 30 outputs a light emission trigger signal delayed by a predetermined time with respect to the droplet detection signal to each of the prepulse laser device 12 and the main pulse laser device 14. The delay time set for each of the prepulse laser device 12 and the main pulse laser device 14 is set so that the droplet 58 is irradiated with the pulse laser light 76 when the droplet 58 reaches the plasma generation region 80.

When the light emission trigger signal is input to the prepulse laser device 12, the prepulse laser light 72 is emitted from the prepulse laser device 12. When the emission trigger signal is input to the main pulse laser device 14, the main pulse laser light 74 is emitted from the main pulse laser device 14. The power of the laser light emitted from the main pulse laser device 14 reaches several kW to several tens of kW. The prepulse laser light 72 emitted from the prepulse laser device 12 passes through the window 46 via the first laser light transmission device 20 and the beam combiner 26, and is input to the chamber 28. The main pulse laser light 74 emitted from the main pulse laser device 14 passes through the window 46 via the second laser light transmission device 22 and the beam combiner 26, and is input to the chamber 28.

The pulse laser light 76 including the prepulse laser light 72 and the main pulse laser light 74 is concentrated by the laser light concentrating unit 50 and is radiated to the droplet 58 reaching the plasma generation region 80.

The droplet 58 is irradiated with at least one pulse included in the pulse laser light 76. The droplet 58 irradiated with the pulse laser light 76 is turned into plasma, and radiation light 116 is radiated from the plasma. EUV light 118 included in the radiation light 116 is selectively reflected by the EUV light concentrating mirror 52. The EUV light 118 reflected by the EUV light concentrating mirror 52 is concentrated at the intermediate focal point 90 and output to the exposure apparatus 110.

Here, one droplet 58 may be irradiated with a plurality of pulses included in the pulse laser light 76. In this example, one droplet 58 is irradiated with a pulse of the prepulse laser light 72, and a pulse of the main pulse laser light 74.

At the timing when one droplet 58 reaches the plasma generation region 80, the droplet 58 is irradiated with the prepulse laser light 72. The droplet 58 irradiated with the prepulse laser light 72 expands or diffuses to become a secondary target. The secondary target may be, for example, a diffusion target diffused in a mist state. At the timing when the secondary target is expanded or diffused to a desired size, the secondary target is irradiated with the main pulse laser light 74. The secondary target irradiated with the main pulse laser light 74 is turned into plasma, and the radiation light 116 including EUV light is radiated from the plasma.

The droplet collector 44 collects the droplet 58 that has passed through the plasma generation region 80 without being irradiated with the pulse laser light 76 and a portion of the droplet 58 that has not been diffused by the irradiation with the pulse laser light 76.

The EUV light sensors 54a, 54b, 54c measure the energy of the EUV light generated in the chamber 28. The controller 30 calculates a plasma centroid position and a drive amount of the laser light concentrating unit 50 necessary for correcting the laser irradiation position using the measurement values obtained from the EUV light sensors 54a, 54b, 54c, and transmits a drive command to the three axis stage 85. The three axis stage 85 is driven in accordance with the drive command from the controller 30 to concentrate the pulse laser light 76 at a predetermined position. The plasma centroid position means the position of the gravity center of EUV energy.

2.3 Arrangement example of EUV light sensor

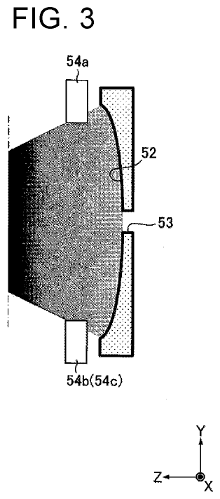

FIGS. 2 and 3 are views exemplarily showing arrangement of EUV light sensors. As shown in FIGS. 2 and 3, the plurality of EUV light sensors 54a, 54b, 54c are arranged around the plasma generation region 80.

That is, the plurality of EUV light sensors 54a, 54b, 54c are arranged on the wall of the chamber 28 so as to face the plasma generation region 80 respectively from different directions. The plurality of EUV light sensor 54a, 54b, 54c are arranged so as not to block the optical path of the EUV light 118 reflected by the EUV light concentrating mirror 52. The plurality of EUV light sensor 54a, 54b, 54c are arranged along the outer circumferential edge of the EUV light concentrating mirror 52. Each of the plurality of EUV light sensor 54a, 54b, 54c is arranged with the light receiving port facing the plasma generation region 80.

The plurality of EUV light sensors 54a, 54b, 54c are arranged at equal distance respectively from the plasma generation region 80 so that the difference in energy measured by the EUV light sensors 54a, 54b, 54c is small when the plasma is generated in the plasma generation region 80. Preferably, the plurality of EUV light sensor 54a, 54b, 54c are arranged at positions where evaluating the EUV centroid position is facilitated.

The EUV centroid position refers to the gravity center of energy distribution of the EUV light 118 in the vicinity of the plasma generation region 80. The EUV centroid position is a position of a weighted average in the energy distribution of the EUV light 118. Specifically, the EUV centroid position is a spatial position specified from a plurality of measurement values obtained by the plurality of EUV light sensors 54a, 54b, 54c.

In order to facilitate evaluating the EUV centroid position, for example, the plurality of EUV light sensors 54a, 54b, 54c are arranged respectively at the vertices of an isosceles right triangle as shown in FIG. 2. The isosceles right triangle shown in FIG. 2 is an isosceles right triangle in which the middle point of the long side passes through the plasma generation region 80 and the two short sides are arranged along the X axis and the Y axis, respectively.

Here, an example is shown in which the EUV light sensor 54c is arranged at the position of the apex angle, the EUV light sensor 54a is arranged in the Y-axis direction from the EUV light sensor 54c, and the EUV light sensor 54b is arranged in the X-axis direction from the EUV light sensor 54c.

Note that the number of the EUV light sensors is not limited to the above, and four or more EUV light sensors may be arranged. It is preferable that at least three EUV light sensors are arranged in the chamber 28 to properly evaluate the EUV centroid position.

### 2.4 Overview of EUV Centroid Control

The EUV centroid control is to control the irradiation position of the laser light with a feedback method so that the EUV centroid position becomes a target centroid position based on the respective measurement results of the plurality of EUV light sensors 54a, 54b, 54c during the generation of the EUV light 118. The irradiation position of the laser light is an irradiation position, in the vicinity of the plasma generation region 80, of the laser light output from the laser light concentrating unit 50 toward the target (i.e., a light concentration position of the laser light), and particularly refers to an irradiation position in a plane orthogonal to the travel direction of the laser light output from the laser light concentrating unit 50. In this example, the irradiation position of the laser light is represented as a position in the XY plane defined by the X axis and Y axis.

An evaluation value for evaluating the EUV centroid position calculated based on a plurality of measurement values obtained from the plurality of EUV light sensors 54a, 54b, 54c is referred to as the “EUV centroid value.”

The target value of the EUV centroid control (target centroid position) is set in advance by sequence operation of the EUV light generation apparatus 11. The controller 30 calculates the EUV centroid value in accordance with the equations (Equation 1A and Equation 1B) for calculating the EUV centroid value based on the outputs of the plurality of EUV light sensors 54a, 54b, 54c.

EUV Centroid_x=(E2−E3)/(E2+E3) (Equation 1A)

EUV Centroid_y=(E1−E3)/(E1+E3) (Equation 1B)

E1 represents the output value of the EUV light sensor 54a. E2 represents the output value of the EUV light sensor 54b. E3 represents the output value of the EUV light sensor 54c.

EUV Centroid_x represents an X-axis coordinate component of the EUV centroid value. EUV Centroid_x indicates the unevenness of the energy distribution of the EUV light in the direction along the X axis. EUV Centroid_y represents a Y-axis coordinate component of the EUV centroid value. EUV Centroid_y indicates the unevenness of the energy distribution of the EUV light in the direction along the Y axis.

The controller 30 calculates the relative positional relationship between the droplet 58 and the irradiation position (light concentration position) of the laser light according to the EUV centroid value calculated from Equation 1A and Equation 1B, and moves the laser light concentrating unit 50 by driving the three axis stage 85 in a direction in which the EUV centroid value becomes a target value.

### 3. Problem

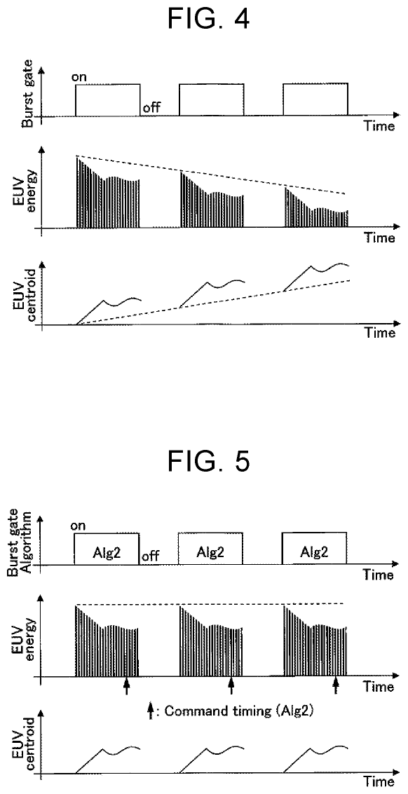

In the EUV light generation apparatus 11, the optical axes of the prepulse laser light 72 and the main pulse laser light 74 are controlled up to the entrance of the beam combiner 26 so that the droplet 58 is irradiated with the prepulse laser light 72 and the main pulse laser light 74 in a positionally accurate manner. However, a deviation occurs in the subsequent optical path, that is, the optical path from the inside of the beam combiner 26 to the exit of the laser light concentrating unit 50. This is because the components in the optical path are distorted by the heat of plasma or laser light. Consequently, laser light is radiated in a positional relationship in which the laser light and the droplet 58 are shifted, the EUV energy becomes unstable, and the amount of unnecessary scattered matters (debris) also increases (see FIG. 4).

FIG. 4 is a graph exemplarily showing a change in the EUV energy and a change in the EUV centroid position in each burst period when the EUV centroid control is not performed. The graph shown at the top of FIG. 4 represents the timing of a burst gate signal. A period in which the burst gate is on is a burst period, and a period in which the burst gate is off is a burst pause period. The burst gate signal is transmitted, for example, from the exposure apparatus control unit 112 to the controller 30.

The controller 30 controls irradiation of the droplet 58 with the prepulse laser light 72 and the main pulse laser light 74 in accordance with the burst gate signal.

The graph shown at the middle of FIG. 4 represents the EUV energy of the EUV light generated in each burst period. In one burst period, the EUV energy is high in the burst beginning part, and the EUV energy is low in the second half of the burst. When comparing between bursts, the EUV energy in the first burst period is the highest, and the EUV energy gradually decreases as the number of bursts increases.

The graph at the bottom of FIG. 4 represents the transition of the EUV centroid position calculated in each burst period. In one burst period, the EUV centroid position shifts from an initial set position. Also, when comparing between bursts, the shift of the EUV centroid position increases as the number of bursts increases.

That is, when the EUV centroid control including the control of the stage position of the laser light concentrating unit 50 is not performed, the EUV centroid position moves away from the initial center as shown in FIG. 4, and the EUV energy decreases between bursts.

With respect to the problem as shown in FIG. 4, in order to stabilize the EUV energy between bursts, feedback control is performed in which the stage position of the laser light concentrating unit 50 is adjusted using the EUV centroid value calculated from the outputs of the EUV light sensors 54a, 54b, 54c to compensate for the irradiation position shift of the laser light with respect to the droplet 58 (see FIG. 5).

FIG. 5 is a graph exemplarily showing the change in the EUV energy and the change in the EUV centroid position in each burst period when the EUV centroid control is performed. The graph shown at the top of FIG. 5 represents the timing of the burst gate signal. The notation “Alg2” in FIG. 5 represents the type of control algorithm applied during the burst gate on period. That is, it is shown that the control by the algorithm Alg2 is performed in the burst period. Note that the algorithm Alg2 is referred to as the “second algorithm Alg2” to distinguish it from the first algorithm Alg1 described later in a first embodiment. Here, “Alg2” represents the algorithm for controlling the irradiation positions of all laser light including the prepulse laser light 72 and the main pulse laser light 74 by moving the laser light concentrating unit 50 based on the EUV centroid value.

The graph shown at the middle of FIG. 5 represents the EUV energy of the EUV light generated in each burst period. The timing indicated by the arrows in this graph represents the timing of the command for instructing the driving of the laser light concentrating unit 50 according to the second algorithm Alg2. That is, the process of the second algorithm Alg2 is executed in the period of the burst gate on, and the movement command signal (command) of the stage position of the laser light concentrating unit 50 is issued at the command timing indicated by the arrows in FIG. 5. According to the command issued at this timing, the three axis stage 85 of the laser light concentrating unit 50 operates. As a result, the energy value of the first pulse in each burst period is kept substantially constant between bursts, and the average EUV energy value in each burst period is kept substantially constant between bursts.

However, with the control by the second algorithm Alg2, since the control speed is low as shown in “command timing” of FIG. 5, correction to the rapid EUV energy reduction phenomenon due to the droplet position variation (hereinafter referred to as “droplet shift”) that occurs significantly at the burst beginning part is insufficient. Since the operation of the control for moving the stage of the laser light concentrating unit 50 is slow, for example, the response frequency is about 10 Hz, it is difficult to correct the fluctuation of the EUV energy due to the droplet shift occurring at the burst beginning part.

The laser light concentrating unit 50 includes a mirror cooling structure for receiving high-power CO2 laser light reaching several tens of kW. The weight of the mirror cooling structure is large, and the response speed of the laser light concentrating unit 50 with the stage becomes approximately 100 ms. Therefore, the EUV energy decrease at the burst beginning part remains as shown in FIG. 5.

### 4. First Embodiment

### 4.1 Overview

To compensate for the droplet shift and the laser irradiation position shift due to the thermal effect at the burst beginning part, in the first embodiment, the actuator to be controlled and the control algorithm are switched in the burst on period. Specifically, an optical element equipped with a high speed actuator that changes the travel direction of the prepulse laser light 72 is arranged on the optical path of the prepulse laser light upstream of the beam combiner 26. Then, in each burst period, the first algorithm Alg1 is applied to control the high speed actuator in a certain period of time in the first half of the burst including the burst beginning part, so that the irradiation position of the prepulse laser light 72 follows the droplet shift occurring at the burst beginning part at high speed. Then, in the second half of the burst after the elapse of a certain period of time, the control algorithm is switched to the second algorithm Alg2, and the laser light concentrating unit 50 is controlled by applying the second algorithm Alg2.

In the first embodiment, Equation 2A and Equation 2B, which will be described later, are used in place of Equation 1A and Equation 1B as the equations for calculating the EUV centroid value.

### 4.2 Configuration

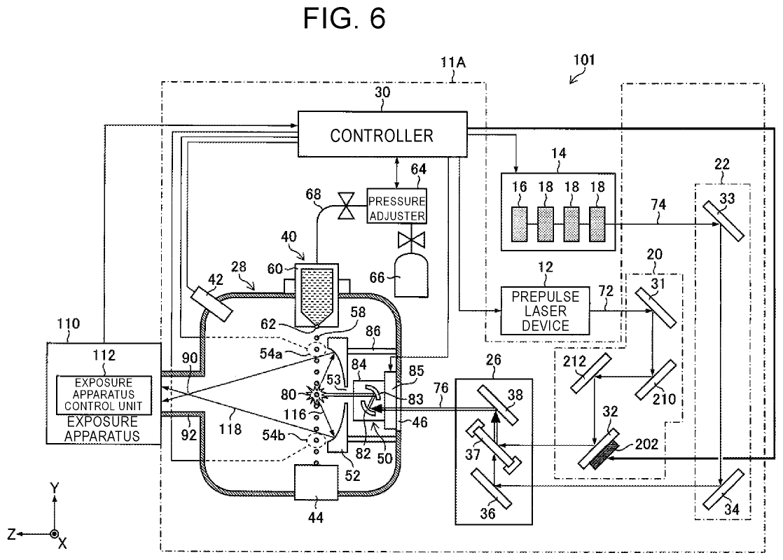

FIG. 6 schematically shows the configuration of an EUV light generation system 101 according to the first embodiment. Differences from FIG. 1 will be described. In the EUV light generation system 101 shown in FIG. 6, a high-speed-actuator-equipped mirror holder 202 having an actuator operating at high speed is arranged on the optical path of the prepulse laser light 72 between the prepulse laser device 12 and the beam combiner 26. To simplify the description, the high-speed-actuator-equipped mirror holder is hereinafter referred to as the “high speed ACT.”

In the high speed ACT 202, a second high reflection mirror 32 is held as an optical element for changing the travel direction of the prepulse laser light 72. In an EUV light generation apparatus 11A shown in FIG. 6, high-reflection mirrors 210, 212 are arranged on the optical path between the first high reflection mirror 31 and the second high reflection mirror 32 in the first laser light transmission device 20. The high reflection mirrors 210 and 212 are arranged so that the laser light reflected by the first high reflection mirror 31 is incident on the second high reflection mirror 32.

Comparing the prepulse laser light 72 and the main pulse laser light 74, it is the prepulse laser light 72 that greatly affects the EUV energy. Therefore, in order to cause the prepulse laser light 72 to follow the droplet shift, which is a high speed phenomenon occurring at the burst beginning part, it is preferable to place the high speed ACT 202 on the optical path of the prepulse laser light 72, as shown in FIG. 6.

The high speed ACT 202 is configured to move the light concentration position (irradiation position) of the prepulse laser light 72 on the XY plane in the plasma generation region 80. Since the high speed ACT 202 holds a mirror (here, the second high reflection mirror 32) that receives the prepulse laser light 72 having energy to such an extent that mirror cooling is unnecessary, a load is small and high speed scanning is possible. The settling time of the high speed ACT 202 may be, for example, 0.01 ms or more and 10 ms or less.

### 4.3 Equation for EUV Centroid Value

Since each of the prepulse laser light 72 and the main pulse laser light 74 (CO2 laser light) has sensitivity with respect to the EUV centroid value, when the prepulse laser light 72 is caused to independently follow the droplet shift, it is necessary to correct the evaluation value of the EUV centroid position (EUV centroid value) in accordance with the relative positional change between the prepulse laser light 72 and the CO2 laser light. To correct the EUV centroid value, it is necessary to use the relative positional deviation amount ΔPPL between the irradiation positions of the prepulse laser light and the CO2 laser light, and the drive amount of the high speed ACT 202 may be used for calculating the relative positional deviation amount ΔPPL1.

For the calculation of the EUV centroid value in the first embodiment, the following equations (Equation 2A and Equation 2B) are used in which a correction member f(ΔPPL) using ΔPPL as a variable is added to the right sides of Equation 1A and Equation 1B. Here, the correction member f(ΔPPL) may be a first-order polynomial, a third-order polynomial, or the like with ΔPPL as a variable.

EUV Centroid_x={(E2−E3)/(E2+E3)}+f(ΔPPLx) (Equation 2A)

EUV Centroid_y={(E1−E3)/(E1+E3)}+f(ΔPPLy) (Equation 2B)

In the above, ΔPPLx represents the value of the relative positional deviation amount of ΔPPL in the X-axis direction, and ΔPPLy represents the value of the relative positional deviation amount of ΔPPL in the Y-axis direction.

### 4.4 Relationship Between Relative Positional Deviation Amount ΔPPL of Prepulse Laser Light and EUV Centroid Position

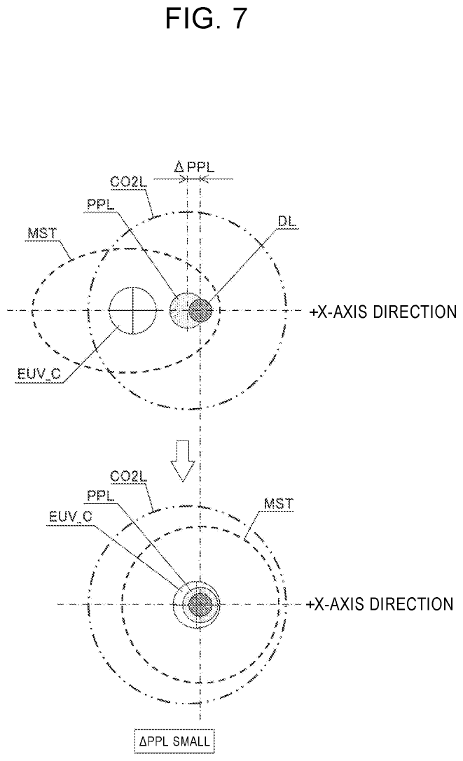

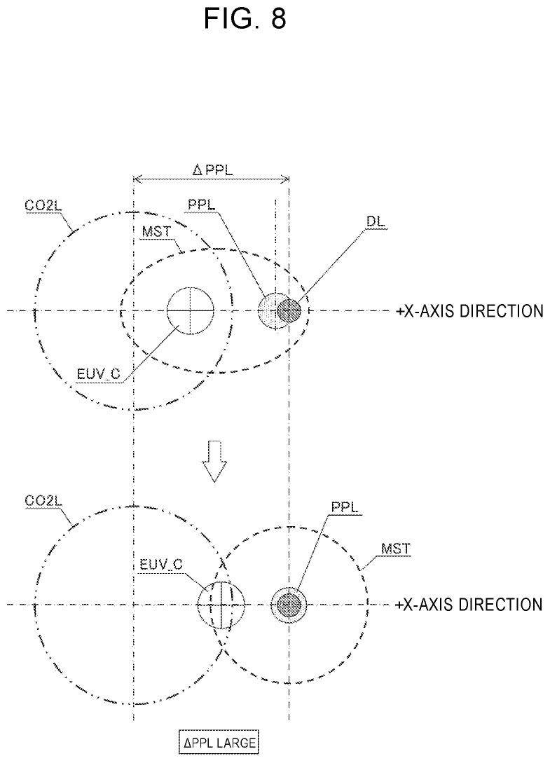

As the relative positional deviation amount (ΔPPL) between the prepulse laser light 72 and the CO2 laser light increases, the feedback control based on the EUV centroid value is more likely to fail. The reason of the above will be described with reference to FIGS. 7 and 8. In each drawing, the gray-filled circle indicated as “DL” represents the position of the droplet 58. In each drawing, the area shown as “PPL” represents the irradiation position of the prepulse laser light 72. In each drawing, the area surrounded by a broken line shown as “MST” represents a mist-generation area of the diffusion target (secondary target) generated by the irradiation with the prepulse laser light 72. In each drawing, the area surrounded by a two-dot chain line shown as “CO2L” represents the irradiation position of CO2 laser light being the main pulse laser light 74.

In each drawing, the overlapping area between the irradiation area of the CO2 laser light surrounded by the two-dot chain line and the mist generation area surrounded by the broken line is substantially the generation region of the EUV light, and the EUV centroid position is schematically shown as the centroid of this region. In each drawing, the position of the mark with a cross in a circle shown as “EUV_C” represents the EUV centroid position.

First, a case where ΔPPL is small as shown in FIG. 7 is considered. When the prepulse laser irradiation position PPL is shifted to the minus side (negative side) in the X-axis direction with respect to the droplet position DL, the EUV centroid value is calculated as a value on the minus side in the X-axis direction. Therefore, the prepulse laser irradiation position PPL is corrected to the plus side (positive side) in the X-axis direction to correct the shift (lower part in FIG. 7). The mist generation range MST of the secondary target generated by irradiating the droplet 58 with the prepulse laser light 72 at the position corrected in this manner is the irradiation range of the CO2 laser light, and the EUV centroid position also approaches the droplet position DL.

Next, a case where ΔPPL is large as shown in the upper part of FIG. 8 will be considered. When the prepulse laser irradiation position PPL is shifted to the minus side in the X-axis direction with respect to the droplet position DL, the prepulse laser irradiation position PPL is corrected to the plus side in the X-axis direction so as to correct the shift (lower part in FIG. 8). When the correction is performed in this manner, only a part of the mist generation range MST on the minus side in the X-axis direction overlaps with the irradiation range of the CO2 laser light. In this case, the EUV centroid value is still calculated as a value on the minus side in the X-axis direction from the prepulse laser irradiation position PPL. Therefore, in the next control, the prepulse laser irradiation position PPL is further moved to the plus side in the X-axis direction so as to correct the above. Then, the mist generation range MST moves to the plus side in the X-axis direction and deviates from the irradiation range of the CO2 laser.

Therefore, such a situation can be avoided by correcting the EUV centroid value by the correction member f(ΔPPL) as a function of ΔPPL as in Equation 2A and Equation 2B.

### 4.5 Operation

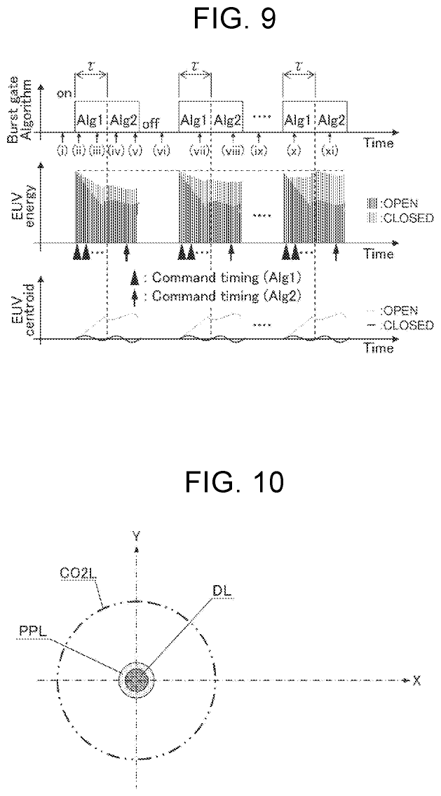

FIG. 9 is a graph showing operation of the EUV light generation system 101 according to the first embodiment. The waveform shown at the top of FIG. 9 represents the burst gate timing. During a certain period T of the first half of the burst from the start of the burst gate rising, the high speed ACT 202 is controlled according to the first algorithm Alg1. Thereafter, in the second half of the burst, the algorithm is switched to the second algorithm Alg2, and the three axis stage 85 of the laser light concentrating unit 50 is controlled in accordance with the second algorithm Alg2. Proportional-integral-differential (PID) control based on the deviation between the EUV centroid value and the target value is applied to the control by the first algorithm Alg1 and the control by the second algorithm Alg2.

The graph shown at the middle of FIG. 9 represents the EUV energy of the EUV light generated in each burst period. The timing indicated by the triangle marks in this graph represents the timing of the command for instructing the driving of the high speed ACT 202 according to the first algorithm Alg1. That is, the process of the first algorithm Alg1 is executed at the burst beginning part which is a predetermined period of time T from the burst start, and the movement command signal (command) of the high speed ACT 202 is issued at the command timing indicated by the triangle marks in FIG. 9. The movement command signal for the high speed ACT 202 based on the first algorithm Alg1 is referred to as the first command. The high speed ACT 202 operates according to the first command.

Further, the process of the second algorithm Alg2 is performed in the second half of the burst after the elapse of time T, and the movement command signal (command) for the laser light concentrating unit 50 is issued at the command timing indicated by the arrows in FIG. 9. The movement command signal for the laser light concentrating unit 50 based on the second algorithm Alg2 is referred to as the second command. According to the second command, the three axis stage 85 of the laser light concentrating unit 50 operates.

The time interval of the timing at which the first command is issued according to the first algorithm Alg1 is sufficiently shorter than the time interval of the timing at which the second command is issued according to the second algorithm Alg2. That is, the response speed of the high speed ACT 202 is higher than that of the three axis stage 85 of the laser light concentrating unit 50.

FIGS. 10 to 20 are schematic diagrams of the vicinity of the plasma generation region 80 at respective timings indicated by (i) to (xi) in FIG. 9. FIG. 10 schematically shows the state of the timing before the first burst irradiation indicated by (i) in FIG. 9. In the state before the first burst irradiation, the positional relationship among the droplet position DL, the prepulse laser irradiation position PPL, and the CO2 laser irradiation position CO2L is appropriately adjusted so that those positions coincide from one another.

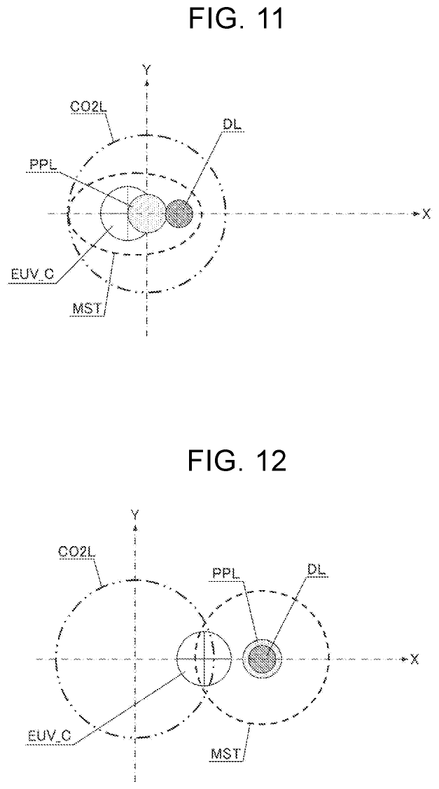

FIG. 11 schematically shows the state of the timing at the burst beginning part indicated by (ii) in FIG. 9. Droplet shift occurs at the burst beginning part just after the burst gate on, and a deviation occurs between the prepulse laser irradiation position PPL and the droplet position DL. Here, a state in which the droplet 58 starts to shift to the plus side in the X-axis direction is shown. Consequently, the EUV centroid value is calculated as a value on the minus side in the X-axis direction.

The controller 30 calculates the EUV centroid value by Equation 2A and Equation 2B using energy values E1, E2, E3 obtained from the respective EUV light sensors 54a, 54b, 54c, and performs feedback control of the high speed ACT 202 so that the calculated EUV centroid value becomes constant. This control algorithm is the first algorithm Alg1.

FIG. 12 schematically shows the state of the timing in the steady state of the droplet shift indicated by (iii) in FIG. 9. Since the high speed ACT 202 is driven by the first algorithm Alg1 with respect to the droplet shift, the prepulse laser irradiation position PPL follows the droplet 58.

After the elapse of time T from the beginning of the burst gate on, the control algorithm is switched to the second algorithm Alg2.

When switching the control algorithm, the co-axial relationship between the prepulse laser light 72 and the CO2 laser light may be restored. During the restoration operation, the three axis stage 85 of the laser light concentrating unit 50 and the high speed ACT 202 are simultaneously moved so that the relationship between the CO2 laser irradiation position CO2L and the prepulse laser irradiation position PPL approaches the optimal positional relationship without largely changing the prepulse laser irradiation position PPL. Specifically, since the laser irradiation positions of both the prepulse laser irradiation position PPL and the CO2 laser irradiation position CO2L are moved when the three axis stage 85 of the laser light concentrating unit 50 is driven, the high speed ACT 202 is simultaneously driven to control the prepulse laser irradiation position PPL to remain at the current position. The “optimal positional relationship” between the CO2 laser irradiation position CO2L and the prepulse laser irradiation position PPL is, for example, the positional relationship in which the largest amount of EUV energy is observed when the droplet 58 is appropriately irradiated with laser.

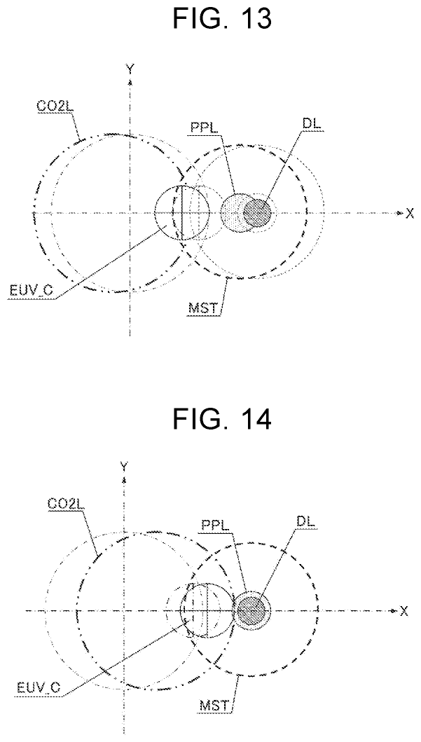

FIG. 13 schematically shows the state of the timing at the second half of the burst indicated by (iv) in FIG. 9. At the timing indicated by (iv), the laser irradiation positions fluctuate due to thermal load.

The controller 30 controls the three axis stage 85 of the laser light concentrating unit 50 based on the energy values E1, E2, E3 obtained from the EUV light sensors 54a, 54b, 54c so that the EUV centroid value calculated by Equation 2A and Equation 2B becomes constant.

FIG. 14 schematically shows the state of the timing at the second half of the burst indicated by (v) in FIG. 9. The timing indicated by (v) in FIG. 9 is a timing after the command timing based on the second algorithm Alg2. That is, the laser light concentrating unit 50 is driven by the second algorithm Alg2 with the EUV centroid value being the control amount, and the fluctuation of the laser irradiation position due to the thermal load is compensated. In the case of this example, the relative positional relationship between the prepulse laser irradiation position PPL and the CO2 laser irradiation position CO2L is corrected while maintaining the relative positional relationship between the droplet position DL and the prepulse laser irradiation position PPL by moving the light concentration position of the laser light concentrating unit 50 in the droplet shift direction and moving the high speed ACT 202 in the direction toward the original position. Thus, the relative positional relationship between the prepulse laser irradiation position PPL and the CO2 laser irradiation position CO2L is restored to a state close to the original state.

The relative positional relationship between the droplet position DL and the prepulse laser irradiation position PPL is referred to as the “relative positional relationship of DL-PPL.” The relative positional relationship between the prepulse laser irradiation position PPL and the CO2 laser irradiation position CO2L is referred to as the “relative positional relationship of PPL-CO2L.”

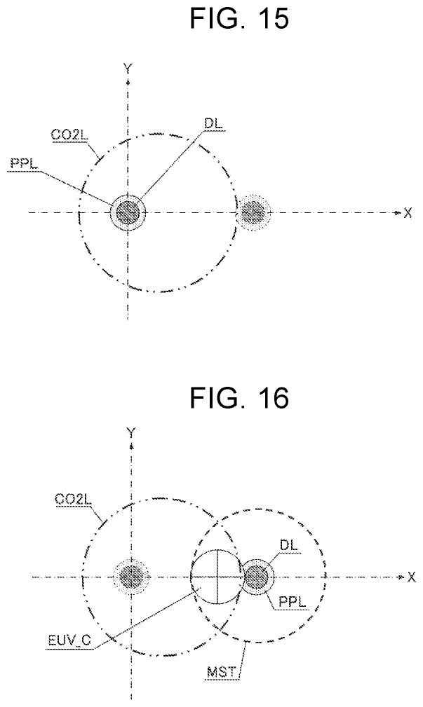

FIG. 15 schematically shows the state of the timing at the burst pause period indicated by (vi) in FIG. 9. The droplet shift occurring at the burst beginning part is restored to the original position with a time constant of about 1 ms to 50 ms at the same time as the burst gate is turned off. Here, the “original position” refers to the initial position before the first burst irradiation described with reference to FIG. 10. Therefore, the controller 30 drives the high speed ACT 202 to match the droplet position (original position). The driving amount at this time is obtained by adding the relative position correction amount of the prepulse laser irradiation position PPL and the CO2 laser irradiation position CO2L to ΔPPL immediately before the burst pause. Further, the drive direction at this time is opposite to the direction of the droplet shift.

The laser irradiation position shift between bursts due to the thermal influence is restored to the original state in the order of seconds to minutes after the burst gate is turned off. In the general burst operation, since the burst pause period is about several tens of ms, the relative positional relationship between the droplet 58 and the prepulse laser light 72 may be restored by the next burst irradiation using the high speed ACT 202 in accordance with the burst gate off. Further, for example, during a long-term operation stop of 1 second or more, it may be the same as the “restoration operation” described in the switching of the control algorithm.

FIG. 16 schematically shows the state of the timing in the steady state of the droplet shift at the burst beginning part indicated by (vii) in FIG. 9. By driving the high speed ACT 202 based on the first algorithm Alg1, the prepulse laser irradiation position PPL follows the position of the droplet. Here, the CO2 laser irradiation position CO2L of the next burst is close to the droplet position in the steady state of the droplet shift by the amount corresponding to the restoration of the relative positional relationship of PPL-CO2L in (v).

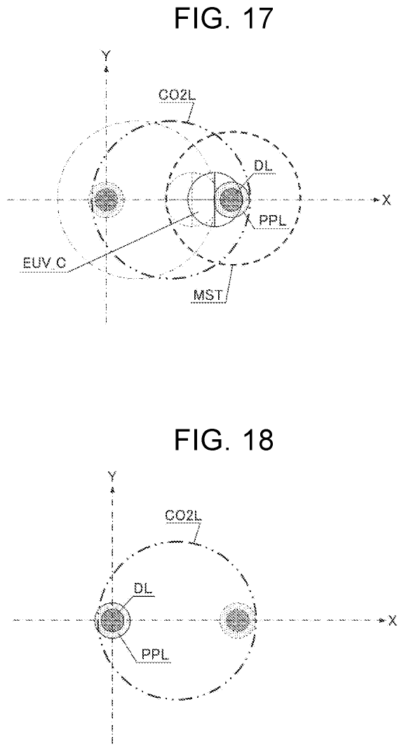

FIG. 17 schematically shows the state of the timing at the second half of the burst indicated by (viii) in FIG. 9. The operation here is the same as the operation of (v) described with reference to FIG. 14. The effect of compensation based on the second algorithm Alg2 is to improve the relative positional relationship of PPL-CO2L in the steady state of the droplet shift.

FIG. 18 schematically shows the state of the timing at the burst pause period indicated by (ix) in FIG. 9. The operation here is the same as the operation of (vi) described with reference to FIG. 15. As the number of bursts increases, the relative positional relationship of PPL-CO2L is gradually restored.

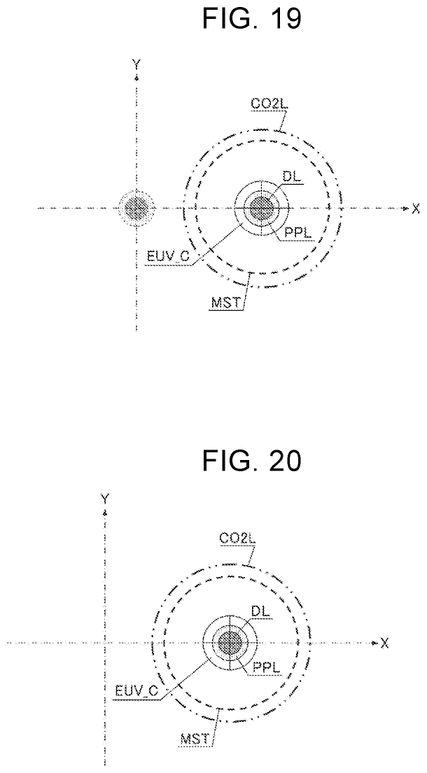

FIG. 19 schematically shows the state of the timing in the steady state of the droplet shift at the burst beginning part indicated by (x) in FIG. 9. The operation here is the same as the operation of (iii) described with reference to FIG. 12 and (vii) described with reference to FIG. 16. Since a plurality of bursts are performed until the timing (x) is reached, the relative positional relationship of PPL-CO2L in the steady state of the droplet shift is completely restored.

FIG. 20 schematically shows the state of the timing at the second half of the burst indicated by (xi) in FIG. 9. The operation here is the same as the operation of (v) described with reference to FIG. 14 and (viii) described with reference to FIG. 17. In the steady state of the droplet shift, the relative positional relationship among the droplet 58, the prepulse laser irradiation position, and the CO2 laser irradiation position can be maintained.

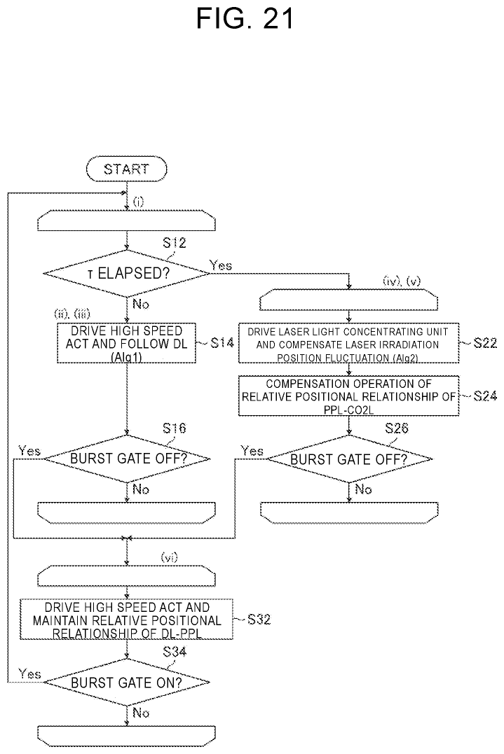

FIG. 21 is a flowchart showing an example of a control operation in the first embodiment. The processing and operation shown in FIG. 21 is realized, for example, by a processor functioning as the controller 30 executing a program.

The indications (i) to (v) in FIG. 21 correspond to the indications (i) to (v) shown in FIG. 9. When the burst gate is turned on, the flowchart of FIG. 21 starts.

In step S12, the controller 30 determines whether the predetermined time T has elapsed from the start of rising of the burst gate on. The time T is a time set in advance to define a period during which the control of the first algorithm Alg1 is performed as shown in FIG. 9. The time T is preferably set to a time substantially equivalent to the time until the droplet shift reaches the steady state (hereinafter referred to as “droplet shift steady state reaching time”). The time T may be set to a time equal to or longer than the droplet shift steady state reaching time.

When the determination result in step S12 is No, the controller 30 proceeds to step S14. In step S14, the controller 30 drives the high speed ACT 202 in accordance with the first algorithm Alg1 to cause the prepulse laser light irradiation position to follow the droplet 58.

In step S16, the controller 30 determines whether the burst gate is off. When the determination result in step S16 is No, the controller 30 returns to step S12. Steps S12 to S16 are repeated until the time T elapses. When the determination result in step S12 is Yes, that is, when the time T has elapsed, the controller 30 proceeds to step S22.

In step S22, the controller 30 drives the laser light concentrating unit 50 in accordance with the second algorithm Alg2 to compensate for laser irradiation position fluctuations due to thermal load. Further, in step S24, the controller 30 performs the compensation operation of the relative positional relationship between the prepulse laser light 72 and the CO2 laser light by combining the driving of the laser light concentrating unit 50 and the driving of the high speed ACT 202. That is, the laser light concentrating unit 50 is moved in the droplet shift direction and the high speed ACT 202 is moved in the direction toward the original position, and the relative positional relationship between the prepulse laser light 72 and the CO2 laser light is restored while maintaining the relative positional relationship between the droplet 58 and the prepulse laser light 72 (see FIG. 14).

Next, in step S26, the controller 30 determines whether the burst gate is off. When the determination result in step S26 is No, the controller 30 returns to step S22. Steps S22 to S26 are repeated until the burst gate is turned off. When the determination result in step S26 is Yes, that is, when the burst gate is off, the controller 30 proceeds to step S32. When the determination result in step S16 is Yes, the controller 30 also proceeds to step S32.

In step S32, the controller 30 drives the high speed ACT 202 in accordance with the position of the droplet that is restored to the original position by the burst pause, and maintains the relative positional relationship between the droplet 58 and the prepulse laser light 72.

Next, in step S34, the controller 30 determines whether the burst gate is on. When the determination result in step S34 is No, that is, when the burst pause period is in progress, the controller 30 returns to step S32. Steps S32 to S34 are repeated until the burst gate is turned on.

When the determination result in step S34 is Yes, that is, when the burst gate is on, the controller 30 returns to step S12, and repeats steps S12 to S34 described above.

### 4.6 Target Value of EUV Centroid Value

The target value of the EUV centroid value is set to the EUV centroid value with which the relative positional relationship among the droplet position, the prepulse laser irradiation position, and the main pulse (CO2 laser) irradiation position is in an optimal state. The optimal state referred to here may be a state in which the EUV energy variation (3σ) in the burst is small and may be the linear center of the EUV centroid characteristic or the like. As a method of setting the target value of the EUV centroid value, for example, the technique described in the specification of WO2017/164251 can be applied.

The variation of the EUV energy in the burst can be evaluated by obtaining the standard deviation σ of the energy of each pulse of the EUV light emitted in the burst and using the value of “3σ.” The EUV centroid characteristic is a characteristic that indicates the relationship between the EUV centroid value measured at different scan positions (scan levels) at the time of scanning with the laser light in the irradiation position of the laser light with respect to the target and each scan level.

When the EUV centroid value measured at each scan level is plotted on a graph with the scan level on the horizontal axis and the EUV centroid value on the vertical axis, the graph of the EUV centroid characteristic (distribution of evaluation values) can be typically fitted using third-order polynomial approximation. A center point (for example, an inflection point) of a portion showing a substantially linear change in the cubic curve can be set to the target value.

### 4.7 Effect

By causing the prepulse laser light 72 to follow the droplet shift occurring at the burst beginning part by the first algorithm Alg1, it is possible to compensate for rapid EUV energy reduction phenomenon in the burst. Further, with respect to the deviation of the irradiation position of the laser light due to the thermal influence accompanying the EUV light emission, all the laser light including the prepulse laser light 72 and the CO2 laser light are caused to follow the droplet 58 by the second algorithm Alg2, so that the EUV energy reduction phenomenon between bursts can be compensated. Thus, it is possible that stable EUV light emission can be achieved during the entire operation period of the burst operation by the EUV light generation system 101.

The droplet generator 40 in the first embodiment is an example of the “target supply unit” in the present disclosure. The high speed ACT 202 is an example of the “first actuator” in the present disclosure, and the second high reflection mirror 32 driven by the high speed ACT 202 is an example of the “first optical element” in the present disclosure. The laser light concentrating unit 50 is an example of the “light concentrating optical system” in the present disclosure. The three axis stage 85 of the laser light concentrating unit 50 is an example of the “second actuator” in the present disclosure. The plasma generation region 80 is an example of the “predetermined region” in the present disclosure. The EUV light sensors 54a, 54b, 54c are examples of “the plurality of sensors” in the present disclosure. Further, the control by the first algorithm Alg1 is an example of the “first control” in the present disclosure, and the control by the second algorithm Alg2 is an example of the “second control” in the present disclosure.

### 5. Second Embodiment

### 5.1 Configuration

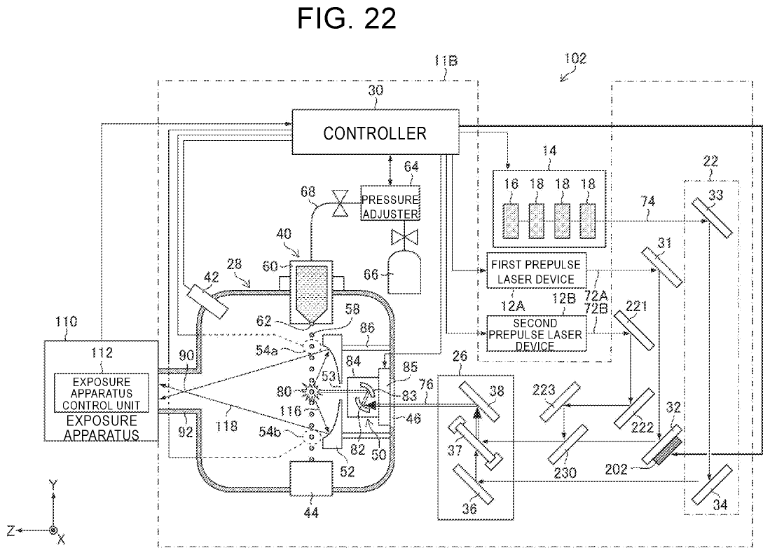

FIG. 22 schematically shows the configuration of an EUV light generation system 102 according to a second embodiment. The EUV light generation system 102 includes a first prepulse laser device 12A and a second prepulse laser device 12B as the prepulse laser device.

The first prepulse laser device 12A is, for example, a laser light source having a wavelength of 1.06 μm and a pulse width of less than 1 ns. The first prepulse laser device 12A may have the same configuration as the prepulse laser device 12 described in FIG. 6. Prepulse laser light emitted from the first prepulse laser device 12A is referred to as first prepulse laser light 72A. The second prepulse laser device 12B is, for example, a laser light source having the same wavelength as the first prepulse laser device 12A (wavelength: 1.06 μm) and a pulse width of 1 ns or more. Prepulse laser light emitted from the second prepulse laser device 12B is referred to as second prepulse laser light 72B.

The EUV light generation apparatus 11B shown in FIG. 22 includes a prepulse multiplexing element 230 that substantially matches the optical path of the first prepulse laser light 72A with the optical path of the second prepulse laser light 72B. The prepulse multiplexing element 230 is arranged on the optical path between the second high reflection mirror 32 having the high speed ACT 202 and the beam combiner 26.

Further, the EUV light generation apparatus 11B includes high reflection mirrors 221, 222, 223 as the laser light transmission optical system that guides the second prepulse laser light 72B emitted from the second prepulse laser device 12B to the prepulse multiplexing element 230.

The first prepulse laser light 72A emitted from the first prepulse laser device 12A and the second prepulse laser light 72B emitted from the second prepulse laser device 12B may be configured such that the polarization directions of the respective laser light on the surfaces of the prepulse multiplexing element 230 are orthogonal to each other. In this case, the prepulse multiplexing element 230 may be configured by a polarization beam splitter.

The first prepulse laser light 72A is guided to the prepulse multiplexing element 230 via the first high reflection mirror 31 and the second high reflection mirror 32. The second prepulse laser light 72B is guided to the prepulse multiplexing element 230 via the high reflection mirrors 221, 222, 223.

The optical paths of the first prepulse laser light 72A and the second prepulse laser light 72B whose optical paths are substantially matched by the prepulse multiplexing element 230 are substantially matched with the optical path of the CO2 laser light in the beam combiner 26. The beam combiner 26 includes the dichroic mirror 37 similarly to the first embodiment.

As shown in FIG. 22, in the case of the configuration including the plurality of prepulse laser devices, it is preferable that the high speed ACT 202 is arranged on the optical path of the prepulse laser light that is firstly radiated to the target supplied to the plasma generation region 80.

The high speed ACT 202 is configured to be capable of moving, on the XY plane in the plasma generation region 80, the light concentration position of the first prepulse laser light 72A firstly radiated to the target.

The droplet target is irradiated with the first prepulse laser light 72A, and a secondary target in which minute droplets of the target substance are dispersed in space is generated.

The secondary target is irradiated with the second prepulse laser light 72B, and fine particles of the target substance are spatially dispersed to generate a density-optimized tertiary target.

As described above, when one target is sequentially irradiated with a plurality of laser light, the first prepulse laser light firstly radiated to the target has large influence on the EUV energy. Therefore, in the EUV centroid control for a high speed droplet shift phenomenon on the order of milliseconds, it is preferable to perform optical axis control using the high speed ACT 202 arranged on the optical path of the first prepulse laser light 72A.

5.2 Equation for EUV centroid value

In the case of the second embodiment, each of the first prepulse laser light 72A, the second prepulse laser light 72B, and the main pulse laser light 74 (CO2 laser light) has sensitivity to the EUV centroid value. Therefore, when the first prepulse laser light 72A independently follows the droplet shift, it is necessary to correct the EUV centroid value in accordance with the relative position change with respect to the second prepulse laser light 72B and the CO2 laser light. The relative positional deviation amount ΔPPL1 of the first prepulse laser light 72A is required to be used for this correction, and the drive amount of the high speed ACT 202 may be used for calculating the relative positional deviation amount ΔPPL1.

For the calculation of the EUV centroid value in the second embodiment, Equation 3A and Equation 3B are used in which a correction member g(ΔPPL) using ΔPPL1 as a variable is added to the right sides of Equation 1A and Equation 1B. The correction member g(ΔPPL1) may be a first-order polynomial or a third-order polynomial with ΔPPL1 as a variable.

EUV Centroid_x={(E2−E3)/(E2+E3)}+g(ΔPPL1x) (Equation 3A)

EUV Centroid_y={(E1−E3)/(E1+E3)}+g(ΔPPL1y) (Equation 3B)

In the above, ΔPPL1x represents the value of the relative positional deviation amount of ΔPPL1 in the X-axis direction, and ΔPPL1y represents the value of the relative positional deviation amount of ΔPPL1 in the Y-axis direction.

The function g of the correction member for ΔPPL1 is changed with respect to the function f of the correction member for ΔPPL applied to the first embodiment. This is because the relationship between ΔPPL1 and the correction amount changes with respect to the relationship between ΔPPL and the correction amount in the first embodiment due to the irradiation with the second prepulse laser light 72B.

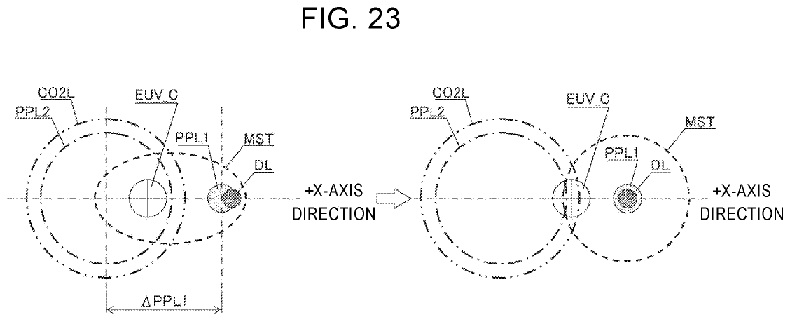

FIG. 23 is a diagram schematically showing the relationship between the EUV centroid position and the relative positional deviation amount ΔPPL1 of the first prepulse laser light 72A with respect to the irradiation positions of the second prepulse laser light 72B and the CO2 laser light. In each drawing, the area shown as “PPL1” represents the irradiation position of the first prepulse laser light 72A. In each drawing, the area surrounded by a chain line shown as “PPL2” represents the irradiation position of the second prepulse laser light 72B.

The left diagram shown in FIG. 23 shows a state in which the irradiation position of the first prepulse laser light 72A is shifted with respect to the droplet 58 due to the droplet shift at the burst beginning part.

The right diagram of FIG. 23 shows a state in which the first prepulse laser irradiation position PPL1 is caused to coincide with the droplet position DL by performing control by the first algorithm Alg1 from the state of the left diagram of FIG. 23.

5.3 Operation

The operation of the EUV light generation system 102 according to the second embodiment will be described. When the burst gate is turned on, the controller 30 controls the high speed ACT 202 based on the energy values obtained from the EUV light sensors 54a, 54b, 54c so that the EUV centroid value calculated by the equations (Equation 3A and Equation 3B) becomes constant. This control algorithm is the first algorithm Alg1.

After the elapse of time T from the beginning of the burst gate on, the controller 30 switches the algorithm to the second algorithm Alg2.

When the algorithm is switched, the coaxial relationship among the first prepulse laser light 72A, the second prepulse laser light 72B, and the CO2 laser light being the main pulse laser light 74 may be restored.

Thereafter, the controller 30 controls the three axis stage 85 of the laser light concentrating unit 50 based on the energy values E1, E2, E3 obtained from the EUV light sensors 54a, 54b, 54c so that the EUV centroid value calculated by the equations (Equation 3A and Equation 3B) becomes constant.

The droplet shift occurring at the burst beginning part is restored to the original position at the same time as the burst gate is turned off. The laser irradiation position shift between bursts due to the thermal influence is restored to the original state in the order of seconds to minutes after the burst gate is turned off.

In order to cope with such a phenomenon, the relative positional relationship between the droplet 58 and the first prepulse laser light 72A may be restored by driving the high speed ACT and the laser light concentrating unit 50 according to the burst gate off.

### 5.4 Effect

According to the second embodiment, by causing the first prepulse laser light 72A to follow the droplet shift occurring at the burst beginning part by the first algorithm Alg1, it is possible to compensate for rapid EUV energy reduction phenomenon in the burst. Further, with respect to the laser light irradiation position shift due to the thermal influence accompanying the EUV light emission, all the laser light of the first prepulse laser light 72A, the second prepulse laser light 72B, and the main pulse laser light 74 (CO2 laser light) are caused to follow by the second algorithm Alg2, so that the EUV energy reduction phenomenon between bursts can be compensated. Consequently, it is possible to stabilize the EUV energy in a burst and between bursts, and it is possible to realize stable EUV light emission during the entire operation period of the burst operation of the EUV light generation apparatus 11B.

According to the second embodiment, even in the EUV light generation system 102 having the triple pulse configuration, the same effects as those of the first embodiment can be achieved.

The prepulse multiplexing element 230 in the second embodiment is an example of the “multiplexing element” in the present disclosure.

### 5.5 Others

The content of the present disclosure can be applied to any configuration regardless of the number of laser light sequentially radiated to one target as long as the laser light firstly radiated to the droplet is controlled by the high speed ACT 202 and at least one of the other laser light is controlled by another actuator (for example, the three axis stage 85 of the laser light concentrating unit 50).

### 6. Third Embodiment

### 6.1 Configuration

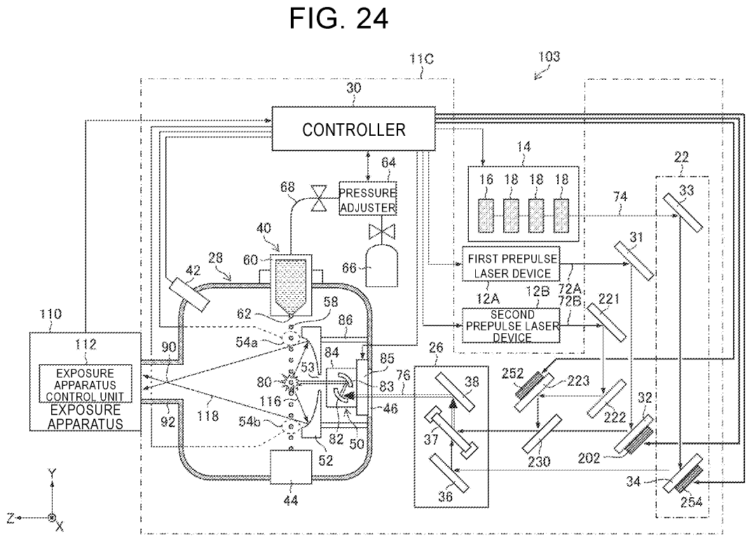

FIG. 24 schematically shows the configuration of an EUV light generation system 103 according to a third embodiment. In FIG. 24, the same or similar elements as those shown in FIG. 22 are denoted by the same reference numerals. Differences from the second embodiment shown in FIG. 22 will be described.

The EUV light generation system 103 according to the third embodiment includes an actuator capable of independently scanning (moving) the first prepulse laser light 72A, the second prepulse laser light 72B, and the main pulse laser light 74 (CO2 laser light).

That is, an EUV light generation apparatus 11C shown in FIG. 24 includes a mirror holder 252 equipped with an actuator on the optical path of the second prepulse laser light 72B. To simplify the description, the mirror holder 252 equipped with an actuator that changes the travel direction of the second prepulse laser light 72B is hereinafter referred to as the “PPL2-ACT 252.” Here, the high reflection mirror 223 is held by the PPL2-ACT 252.

The PPL2-ACT 252 is configured to move the light concentration position (irradiation position) of the second prepulse laser light 72B on the XY plane in the plasma generation region 80. The PPL2-ACT 252 functions as an actuator for scanning the second prepulse laser irradiation position PPL2.

The EUV light generation apparatus 11C according to the third embodiment includes a mirror holder 254 equipped with an actuator on the optical path of the CO2 laser light. To simplify the description, the mirror holder 254 equipped with an actuator that changes the travel direction of the CO2 laser light is hereinafter referred to as the “CO2L-ACT 254.” Here, the fourth high reflection mirror 34 is held by the CO2L-ACT 254.

The CO2L-ACT 254 is configured to move the light concentration position (irradiation position) of the CO2 laser light on the XY plane in the plasma generation region 80.

### 6.2 Operation

Regarding the operation of the EUV light generation system 103 according to the third embodiment, differences from the operations of the first and second embodiments will be described. The first embodiment and the second embodiment adopt the configuration in which the laser light concentrating unit 50 is moved when all the laser light is moved on the XY plane in the plasma generation region 80 by the second algorithm Alg2 in the second half of the burst. In contrast, in the case of the configuration described in the third embodiment, the high speed ACT 202, the PPL2-ACT 252, and the CO2L-ACT 254 are synchronously driven instead of driving of the laser light concentrating unit 50.

In the third embodiment, the high speed ACT 202 is controlled in the same manner as in the second embodiment, and the function of the three axis stage 85 of the laser light concentrating unit 50 is realized by a combination of the PPL2-ACT 252 and the CO2L-ACT 254. Therefore, in the third embodiment, it is not necessary to control the three axis stage 85. Instead, in the EUV light generation system 103 according to the third embodiment, the PPL2-ACT 252 and the CO2L-ACT 254 are driven so as to maintain the positional relationship between the second prepulse laser irradiation position PPL2 and the CO2 laser irradiation position CO2L. Here, since the difference in irradiation time between the second prepulse laser light 72B and the CO2 laser light is small, it is not necessary to consider the positional variation of the target during this period. Therefore, from the viewpoint of stabilizing the EUV energy in the burst, the necessity of independently controlling both the irradiation positions is low.

### 6.3 Effect

In the case of the EUV light generation system 103 according to the third embodiment, the fourth high reflection mirror 34 includes a mirror cooling structure (not shown) so that the fourth high reflection mirror 34 driven by the CO2L-ACT 254 is resistant to the high-power CO2 laser light. Therefore, the CO2L-ACT 254 cannot be expected to respond as quickly as the high speed ACT 202.

However, since the fourth high reflection mirror 34 can be configured to be lighter than the laser light concentrating unit 50, the control cycle of the second algorithm Alg2 can be increased in the third embodiment as compared with the first embodiment and the second embodiment. Therefore, according to the third embodiment, the stability of the EUV energy in the burst is further improved.

The high reflection mirror 223 in the third embodiment is an example of the “second optical element” in the present disclosure. The PPL2-ACT 252 that moves the high reflection mirror 223 is an example of the “third actuator” in the present disclosure. The fourth high reflection mirror 34 is an example of the “third optical element” in the present disclosure. The CO2L-ACT 254 that moves the fourth high reflection mirror 34 is an example of the “fourth actuator” in the present disclosure.

### 7. Fourth Embodiment

### 7.1 Configuration

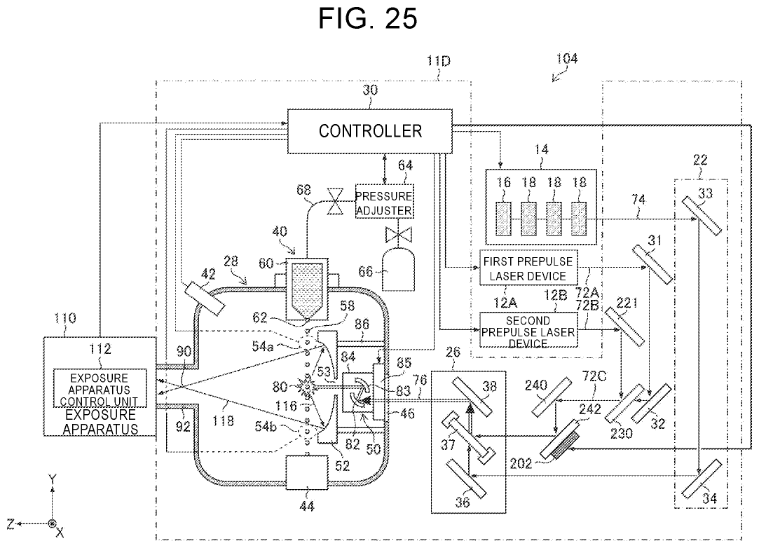

FIG. 25 schematically shows the configuration of an EUV light generation system 104 according to a fourth embodiment. In FIG. 25, the same or similar elements as those shown in FIG. 22 are denoted by the same reference numerals. Differences from the second embodiment shown in FIG. 22 will be described.

In the case of a system configuration including a plurality of prepulse laser devices, the high speed ACT 202 may be arranged on an optical path in which a plurality of prepulse laser light are multiplexed. In an EUV light generation apparatus 11D shown in FIG. 25, the high speed ACT 202 is arranged on the optical path between the prepulse multiplexing element 230 and the beam combiner 26. The EUV light generation apparatus 11D includes high reflection mirrors 240, 242 that guide the prepulse laser light 72C output from the prepulse multiplexing element 230 to the beam combiner 26. The high reflection mirror 242 is held by the high speed ACT 202. The high speed ACT 202 is configured to be capable of moving the light concentration position of the prepulse laser light 72C on the XY plane in the plasma generation region 80.

### 7.2 Equation for EUV Centroid Value

In the case of the fourth embodiment, each of the first prepulse laser light 72A, the second prepulse laser light 72B, and the CO2 laser light has sensitivity to the EUV centroid value. Therefore, when the prepulse laser light 72C obtained by combining the first prepulse laser light 72A and the second prepulse laser light 72B is caused to follow the droplet shift using the high reflection mirror 242, it is preferable to correct the EUV centroid value in accordance with a change in the relative position between the CO2 laser light and the prepulse laser light 72C.

For this correction, the relative positional deviation amount ΔPPL1_2 between the CO2 laser light and the prepulse laser light 72C is used. The drive amount of the high speed ACT 202 may be used to calculate ΔPPL1-2. For the calculation of the EUV centroid value in the fourth embodiment, the equations (Equation 4A and Equation 4B) are used in which a correction member h(ΔPPL 2) using ΔPPL1_2 as a variable is added to the right sides of Equation 1A and Equation 1B. The correction member h(ΔPPL1_2) may be a first-order polynomial or a third-order polynomial with ΔPPL1_2 as a variable.

EUV Centroid_x={(E2−E3)/(E2+E3)}+h(ΔPPL1_2x) (Equation 4A)

EUV Centroid_y={(E1−E3)/(E1+E3)}+h(ΔPPL1_2y) (Equation 4B)

In the above, ΔPPL1_2x represents the value of the relative positional deviation amount of ΔPPL1_2 in the X-axis direction, and ΔPPL1_2y represents the value of the relative positional deviation amount of ΔPPL1_2 in the Y-axis direction.

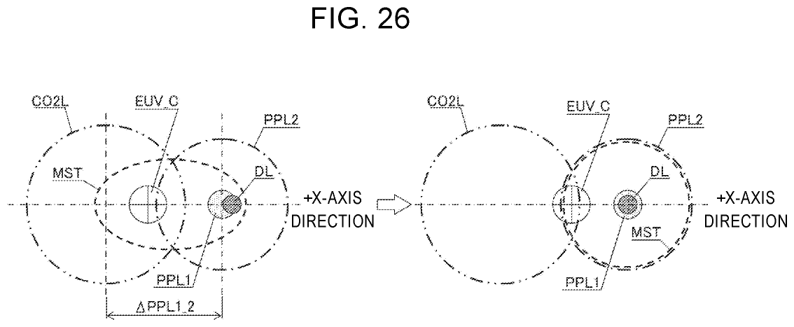

FIG. 26 is a diagram schematically showing the relationship between the EUV centroid position and the relative positional deviation amount ΔPPL1_2 of the irradiation positions of the prepulse laser light and the CO2 laser light. The description rule of FIG. 26 is the same as that of FIG. 23. The left diagram in FIG. 26 shows a state in which the irradiation position of the first prepulse laser light 72A and the second prepulse laser light 72B is shifted with respect to the droplet 58 due to the droplet shift at the burst beginning part.

The right diagram of FIG. 26 shows a state in which the first prepulse laser irradiation position PPL1 and the second prepulse laser irradiation position PPL2 are caused to coincide with the droplet position DL by performing control by the first algorithm Alg1 from the state of the left diagram of FIG. 26.

### 7.3 Operation

Regarding the operation of the EUV light generation system 104 according to the fourth embodiment, differences from the operations of the first and second embodiments will be described. In the case of the configuration shown in the fourth embodiment, the high speed ACT 202 is controlled by the first algorithm Alg1. Thereafter, the same control as in the second embodiment is performed by the second algorithm Alg2.

### 7.4 Effect

According to the fourth embodiment, the laser irradiation position can follow the droplet shift while maintaining the relative positional relationship between the first prepulse laser irradiation position PPL1 and the second prepulse laser irradiation position PPL2. According to the fourth embodiment, the amount of EUV energy decrease due to the collapse of the relative positional relationship of the laser light can be reduced, and the EUV energy stability in the burst is further improved.

The high reflection mirror 242 in the fourth embodiment is an example of the “first optical element” in the present disclosure.

### 8. Example of Electronic Device Manufacturing Method Using EUV Light Generation System

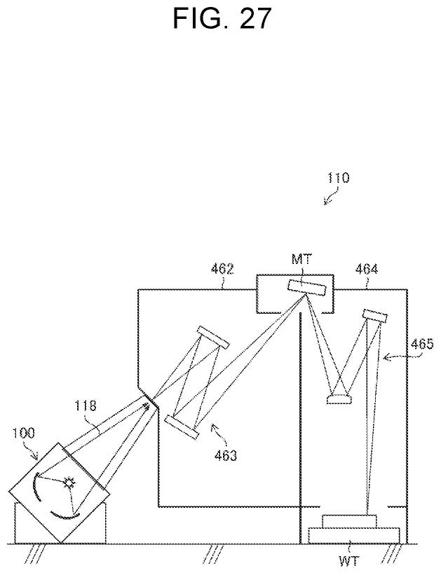

FIG. 27 is a diagram showing a schematic configuration of the exposure apparatus 110 connected to the EUV light generation system 100. In FIG. 27, the exposure apparatus 110 includes a mask irradiation unit 462 and a workpiece irradiation unit 464. The mask irradiation unit 462 illuminates, via a reflection optical system 463, a mask pattern of a mask table MT with the EUV light 118 incident from the EUV light generation system 100.

The workpiece irradiation unit 464 images the EUV light 118 reflected by the mask table MT onto a workpiece (not shown) arranged on the workpiece table WT through a reflection optical system 465.

The workpiece is a photosensitive substrate such as a semiconductor wafer on which photoresist is applied. The exposure apparatus 110 synchronously translates the mask table MT and the workpiece table WT to expose the workpiece to the EUV light reflecting the mask pattern.

Through the exposure process as described above, a device pattern is transferred onto the semiconductor wafer, thereby a semiconductor device can be manufactured. The semiconductor device is an example of the “electronic device” in the present disclosure. The EUV light generation system 100 connected to the exposure apparatus 110 may be any of the EUV light generation systems 101 to 104 described in the embodiments.

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that embodiments of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of any thereof and any other than A, B, and C.

What is claimed is:

1. An extreme ultraviolet light generation system, comprising:
a chamber;
a target supply unit configured to supply a target to a predetermined region in the chamber;
a prepulse laser device configured to emit prepulse laser light to be radiated to the target;
a main pulse laser device configured to emit main pulse laser light to be radiated to the target irradiated with the prepulse laser light;
a beam combiner configured to substantially match an optical path of the prepulse laser light and an optical path of the main pulse laser light;
a light concentrating optical system arranged on an optical path of the prepulse laser light and the main pulse laser light output from the beam combiner and configured to concentrate the prepulse laser light and the main pulse laser light on the vicinity of the predetermined region;
a first optical element arranged on the optical path of the prepulse laser light between the prepulse laser device and the beam combiner;
a first actuator configured to change a travel direction of the prepulse laser light to be output from the first optical element;
a second actuator configured to change irradiation positions of the prepulse laser light and the main pulse laser light in a plane orthogonal to the travel direction of the prepulse laser light and the main pulse laser light output from the light concentrating optical system;
a plurality of sensors configured to detect light radiated from the predetermined region by the target being irradiated with the main pulse laser light; and
a controller configured to control the first actuator and the second actuator based on output of the plurality of sensors, as performing, within one burst period, first control to control the first actuator so that an evaluation value calculated from the output of the plurality of sensors approaches a target value, and after the first control, second control to control the second actuator so that the evaluation value approaches the target value.

2. The extreme ultraviolet light generation system according to claim 1,
wherein the evaluation value is a value for evaluating a centroid position of the light radiated from the predetermined region.

3. The extreme ultraviolet light generation system according to claim 2,
wherein an equation for calculating the evaluation value includes a correction member represented by a function using, as a variable, a relative positional deviation amount between the irradiation position of the prepulse laser light and the irradiation position of the main pulse laser light.

4. The extreme ultraviolet light generation system according to claim 1,
wherein the first actuator is arranged to drive the first optical element.

5. The extreme ultraviolet light generation system according to claim 1,
wherein the second actuator is arranged to drive the light concentrating optical system.

6. The extreme ultraviolet light generation system according to claim 1,
wherein the controller outputs a first command, which is a command signal for driving the first actuator, in the first control, and outputs a second command, which is a command signal for driving the second actuator, in the second control,
and a time interval of timings at which the first command is output is shorter than a time interval of timings at which the second command is output.

7. The extreme ultraviolet light generation system according to claim 1,
wherein response speed of the first actuator is higher than response speed of the second actuator.

8. The extreme ultraviolet light generation system according to claim 1,
wherein the controller performs the first control during a predetermined period at beginning of the burst period, and performs the second control after the predetermined period elapses.

9. The extreme ultraviolet light generation system according to claim 8,
wherein, when performing the second control, the controller corrects relative positional relationship between the irradiation position of the prepulse laser light and the irradiation position of the main pulse laser light by driving the second actuator while maintaining relative positional relationship, actualized by the first control, between the target and the irradiation position of the prepulse laser light by driving the first actuator driven by the first control in a direction toward an original position.

10. The extreme ultraviolet light generation system according to claim 1,
wherein the controller drives the first actuator in a direction opposite to a direction of driving by the first control during a burst pause period.

11. The extreme ultraviolet light generation system according to claim 1,
wherein the prepulse laser device includes a first prepulse laser device emitting first prepulse laser light to be firstly radiated to the target supplied to the predetermined region, and a second prepulse laser device emitting second prepulse laser light to be radiated to the target irradiated with the first prepulse laser light, and
the first optical element provided with the first actuator is arranged on an optical path of the first prepulse laser light between the first prepulse laser device and the beam combiner.

12. The extreme ultraviolet light generation system according to claim 11,
further comprising a multiplexing element configured to substantially match an optical path of the first prepulse laser light and an optical path of the second prepulse laser light,
wherein the first prepulse laser light and the second prepulse laser light output from the multiplexing element are caused to enter the beam combiner, and
the first optical element provided with the first actuator is arranged on an optical path between the first prepulse laser device and the multiplexing element.

13. The extreme ultraviolet light generation system according to claim 11,
wherein an equation for calculating the evaluation value includes a correction member represented by a function using, as a variable, a relative positional deviation amount between an irradiation position of the first prepulse laser light and the irradiation position of the main pulse laser light.

14. The extreme ultraviolet light generation system according to claim 11,
further comprising a second optical element arranged on an optical path of the second prepulse laser light between the second prepulse laser device and the beam combiner and a third optical element arranged on the optical path of the main pulse laser light between the main pulse laser device and the beam combiner,
wherein the second actuator includes a third actuator driving the second optical element and a fourth actuator driving the third optical element, and
the controller drives, in the second control, the third actuator and the fourth actuator so that relative positional relationship between an irradiation position of the second prepulse laser light and the irradiation position of the main pulse laser light is maintained.

15. The extreme ultraviolet light generation system according to claim 11,
further comprising a multiplexing element configured to substantially match the optical path of the first prepulse laser light and an optical path of the second prepulse laser light,
wherein the first optical element provided with the first actuator is arranged on an optical path between the multiplexing element and the beam combiner.

16. The extreme ultraviolet light generation system according to claim 15,
wherein an equation for calculating the evaluation value includes a correction member represented by a function using, as a variable, a relative positional deviation amount between the irradiation position of prepulse laser light output from the multiplexing element including the first prepulse laser light and the second prepulse laser light and the irradiation position of the main pulse laser light.

17. The extreme ultraviolet light generation system according to claim 1,
wherein the first control and the second control are both PID control.

18. An electronic device manufacturing method, comprising:
generating extreme ultraviolet light as turning a target into plasma by irradiating the target with prepulse laser light and main pulse laser light using an extreme ultraviolet light generation system;
emitting the extreme ultraviolet light to an exposure apparatus; and
exposing a photosensitive substrate to the extreme ultraviolet light in the exposure apparatus to manufacture an electronic device,
the extreme ultraviolet light generation system including:
a chamber;
a target supply unit configured to supply the target to a predetermined region in the chamber;
a prepulse laser device configured to emit the prepulse laser light to be radiated to the target;
a main pulse laser device configured to emit the main pulse laser light to be radiated to the target irradiated with the prepulse laser light;
a beam combiner configured to substantially match an optical path of the prepulse laser light and an optical path of the main pulse laser light;
a light concentrating optical system arranged on an optical path of the prepulse laser light and the main pulse laser light output from the beam combiner and configured to concentrate the prepulse laser light and the main pulse laser light on the vicinity of the predetermined region;
a first optical element arranged on the optical path of the prepulse laser light between the prepulse laser device and the beam combiner;
a first actuator configured to change a travel direction of the prepulse laser light to be output from the first optical element;
a second actuator configured to change irradiation positions of the prepulse laser light and the main pulse laser light in a plane orthogonal to a travel direction of the prepulse laser light and the main pulse laser light output from the light concentrating optical system;
a plurality of sensors configured to detect light radiated from the predetermined region by the target being irradiated with the main pulse laser light; and a controller configured to control the first actuator and the second actuator based on output of the plurality of sensors, as performing, within one burst period, first control to control the first actuator so that an evaluation value calculated from the output of the plurality of sensors approaches a target value, and after the first control, second control to control the second actuator so that the evaluation value approaches the target value.
